(19) United States
(12) Patent Application Publication
(10) Pub. No.: US 2026/0068120 A1
(43) Pub. Date: Mar. 5, 2026

(54) SEMICONDUCTOR DEVICE AND METHOD FOR FABRICATING THE SAME

(71) Applicant: SK hynix Inc., Gyeonggi-do (KR)

(72) Inventors: Jeong Hoon KWON, Gyeonggi-do (KR); Dong Il SONG, Gyeonggi-do (KR)

(21) Appl. No.: 19/064,711

(22) Filed: Feb. 27, 2025

(30) Foreign Application Priority Data
Aug. 27, 2024 (KR) 10-2024-0115013

(51) Int. Cl. H10B 12/00

(52) U.S. Cl. CPC H10B 12/30; H10B 12/03; H10B 12/05

(57) ABSTRACT

A semiconductor device may include high-integrated memory cells, and a method for fabricating the semiconductor device may include forming a mold stack including a plurality of preliminary nano-sheets over a substrate; forming a target layer surrounding portions of the preliminary nano-sheets; performing a first horizontal recess process on the target layer and forming a preliminary horizontal conductive line; and performing a second horizontal recess process on the preliminary horizontal conductive line and forming a horizontal conductive line.

### CROSS-REFERENCE TO RELATED APPLICATIONS

The present application claims priority under 35 U.S.C 119(a) to Korean Patent Application No. 10-2024-0115013, filed on Aug. 27, 2024, which is incorporated herein by reference in its entirety.

### BACKGROUND

### 1. Field

Various embodiments of the present disclosure relate to a semiconductor device, and more particularly, to a semiconductor device including three-dimensional (3D) memory cells, and a method for fabricating the semiconductor device.

### 2. Description of the Related Art

Recently, in order to cope with the trend of large capacity and miniaturization of a memory device, a three-dimensional (3D) memory device in which a plurality of memory cells are stacked has been proposed.

### SUMMARY

Embodiments of the present disclosure provide a novel 3D structure and performance semiconductor device with improved characteristics and are directed to a semiconductor device including high-integrated memory cells, and a method for fabricating the semiconductor device.

In accordance with an embodiment of the present disclosure, a method for fabricating a semiconductor device may include forming a mold stack including a plurality of preliminary nano-sheets over a substrate; forming a target layer surrounding portions of the preliminary nano-sheets; performing a first horizontal recess process on the target layer and forming a preliminary horizontal conductive line; and performing a second horizontal recess process on the preliminary horizontal conductive line and forming a horizontal conductive line.

In accordance with an embodiment of the present disclosure, a semiconductor device may include a plurality of nano-sheets that are vertically disposed; horizontal conductive lines surrounding the nano-sheets, respectively; a vertical conductive line coupled in common to first sides of the nano-sheets; data storage elements coupled to second sides of the nano-sheets, respectively; and inter-cell dielectric layers disposed between the data storage elements and horizontally extending to be in contact with the horizontal conductive lines.

In accordance with an embodiment of the present disclosure, a semiconductor device may include a plurality of nano-sheets that are vertically disposed; a first conductive line coupled in common to first edges of the nano-sheets; data storage elements coupled to second edges of the nano-sheets, respectively; second conductive lines surrounding the nano-sheets, respectively; first inter-cell horizontal dielectric layers disposed between the second conductive lines; and second inter-cell horizontal dielectric layers disposed between the data storage elements and horizontally extending to contact the horizontal conductive lines.

In accordance with an embodiment of the present disclosure, a semiconductor device may include column and row arrays of horizontal layers; horizontal conductive lines surrounding the horizontal layers in the row array in common and respectively surrounding the horizontal layers in the column array; data storage elements respectively coupled to the horizontal layers in the column and row arrays; vertical conductive lines coupled in common to the horizontal layers in the column array and respectively coupled to the horizontal layers in the row array; first inter-cell dielectric layers disposed between the data storage elements in the row array; second inter-cell dielectric layers disposed between the horizontal conductive lines in the column array; and third inter-cell dielectric layers disposed between the data storage elements in the column array. Each of the third inter-cell dielectric layers may include a spacer extending to be coupled to the horizontal conductive lines.

In accordance with an embodiment of the present disclosure, a method for fabricating a semiconductor device may include forming a mold stack including nano-sheet target layers that are vertically stacked over a substrate; trimming first portions of the nano-sheet target layers to form narrow sheets; forming a target layer surrounding each of the narrow sheets; performing a first horizontal recess process on the target layer to form a preliminary horizontal conductive line; forming a vertical conductive line coupled in common to the narrow sheets; horizontally recessing second portions of the nano-sheet target layers to form wide sheets; performing a second horizontal recess process on the preliminary horizontal conductive line to form a horizontal conductive line surrounding each of the narrow sheets; and forming data storage elements coupled to the wide sheets, respectively.

These and other features and advantages of the embodiments of the present disclosure will become apparent to the skilled person with ordinary skill in the art from the following detailed description and drawings.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view of the memory cell illustrated in FIG. 1A.

FIG. 2A is a schematic view illustrating a semiconductor device in accordance with an embodiment of the present disclosure.

FIG. 2B is a schematic perspective view illustrating a memory cell array illustrated in FIG. 2A.

FIG. 2C is an equivalent circuit view of a column array illustrated in FIG. 2B.

FIG. 2D is an equivalent circuit view of a row array illustrated in FIG. 2B.

FIG. 3 is a schematic plan view illustrating a semiconductor device in accordance with an embodiment of the present disclosure.

FIG. 4A is a cross-sectional view of the semiconductor device taken along line A-A′ illustrated in FIG. 3.

FIG. 4B is a cross-sectional view of the semiconductor device taken along line B-B′ illustrated in FIG. 3.

FIGS. 5 to 30 illustrate various views of a semiconductor device formed utilizing a method for fabricating the semiconductor device in accordance with an embodiment of the present disclosure.

FIG. 31 illustrates a view of a semiconductor device formed utilizing a method for fabricating the semiconductor device in accordance with an embodiment of the present disclosure.

FIGS. 32 and 33 are schematic cross-sectional views of a semiconductor device in accordance with embodiments of the present disclosure.

FIGS. 34 and 35 illustrate various views illustrating a stack assembly in accordance with embodiments of the present disclosure.

### DETAILED DESCRIPTION

Various embodiments of the present disclosure may be described herein with reference to cross-sectional views, plan views and block diagrams, which are ideal schematic views of a semiconductor device. It is noted that the structures of the drawings may be modified by fabricating techniques and/or tolerances. The embodiments of the present disclosure are not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the embodiments of the present disclosure.

The following embodiment relates to three-dimensional (3D) memory cells with memory cells vertically stacked for increasing the memory cell density and reducing parasitic capacitance.

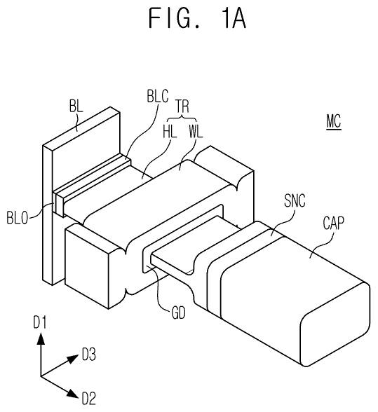

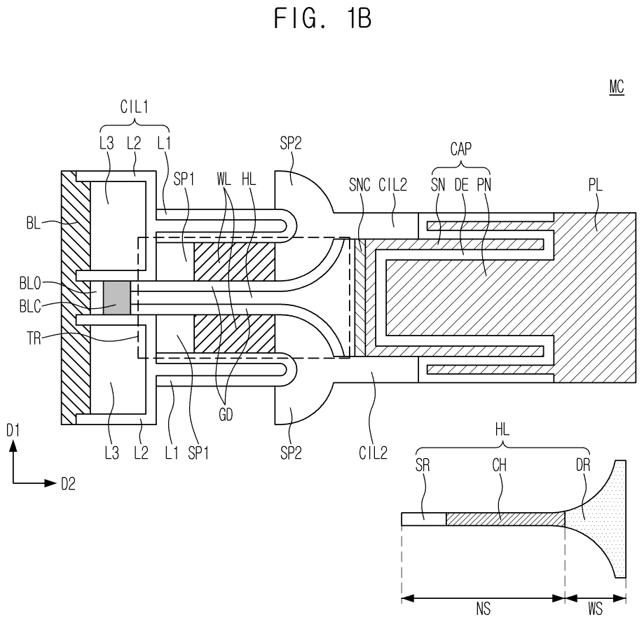

FIG. 1A is a schematic perspective view illustrating a memory cell MC in accordance with an embodiment of the present disclosure. FIG. 1B is a schematic cross-sectional view of the memory cell MC illustrated in FIG. 1A.

Referring to FIGS. 1A and 1B, the memory cell MC may include a first conductive line BL, a switching element TR, and a data storage element CAP.

The first conductive line BL may be vertically oriented in a first direction D1. The first conductive line BL may include a bit line. The first conductive line BL may be referred to as a “vertical conductive line”, a “vertically-oriented bit line”, a “vertically-extending bit line”, or a “pillar-shaped bit line”. The first conductive line BL may include a conductive material. The first conductive line BL may include a silicon-based material, a metal-based material, or a combination thereof. The first conductive line BL may include polysilicon, metal, metal nitride, metal silicide, or a combination thereof. The first conductive line BL may include polysilicon, titanium nitride, tungsten, or a combination thereof. For example, the first conductive line BL may include a titanium nitride/tungsten (TiN/W) stack in which titanium nitride and tungsten are sequentially stacked.

The switching element TR has a function of controlling the voltage or the current supply to the data storage element CAP during data write and data read operations performed onto the data storage element CAP. The switching element TR may include a nano-sheet HL, a nano-sheet dielectric layer GD, and a second conductive line WL. The second conductive line WL may include a horizontal conductive line or a horizontal word line, and the nano-sheet HL may include an active layer. The switching element TR may include a transistor, and in this case, the second conductive line WL may serve as a gate electrode. The switching element TR may also be referred to as a “nano-sheet transistor”, an “access element” or a “selection element”. The second conductive line WL may be referred to as a “horizontal gate electrode” or a “horizontal word line”.

The nano-sheet HL may extend in a second direction D2 that intersects with the first direction D1. The second conductive line WL may extend in a third direction D3 that intersects with the first direction D1 and the second direction D2. The first direction D1 may be a vertical direction, the second direction D2 may be a first horizontal direction, and the third direction D3 may be a second horizontal direction. The nano-sheet HL may extend in the first horizontal direction, i.e., the second direction D2, and the second conductive line WL may extend in the second horizontal direction, i.e., the third direction D3. The nano-sheet HL may be referred to as a “horizontal layer”.

The nano-sheet HL may include a channel CH, a first doped region SR between the channel CH and the first conductive line BL, and a second doped region DR between the channel CH and the data storage element CAP. The first doped region SR may be electrically coupled to the first conductive line BL, and the second doped region DR may be electrically coupled to the data storage element CAP. The height of the second doped region DR in the first direction D1 may be greater than the heights of the first doped region SR and the channel CH in the first direction D1. The length of the second doped region DR in the second direction D2 may be less than that of the channel CH in the second direction D2. The lengths of the first doped region SR, the channel CH and the second doped region DR in the third direction D3 may be equal to one another.

The nano-sheet HL may include a first region NS and a second region WS that are horizontally disposed in the second direction D2. The second region WS may extend from the first region NS. The second region WS may have a thickness that gradually increases in the second direction D2 from the first region NS toward the data storage element CAP between the first region NS and the data storage element CAP. An average vertical height or thickness of the second region WS in the first direction D1 may be greater than that of the first region NS. Hereinafter, the first region NS is referred to as a “narrow sheet”, and the second region WS is referred to as a “wide sheet”.

The narrow sheet NS may have a flat plate shape. The wide sheet WS may have a fan-like shape. The wide sheet WS may have a thickness that gradually increases in the second direction D2. The narrow sheet NS may be referred to as a “flat plate-shaped sheet”, and the wide sheet WS may be referred to as a “fan-like shaped sheet”. A boundary portion between the narrow sheet NS and the wide sheet WS may have a curvature.

The first doped region SR and the channel CH may be disposed in the narrow sheet NS. The second doped region DR may be disposed in the wide sheet WS. The channel CH formed in the narrow sheet NS may be referred to as a “narrow channel” or a “flat channel”. A portion of the second doped region DR may extend to be disposed in the narrow sheet NS. The second doped region DR may include a thick portion disposed in the wide sheet WS and a thin portion disposed in the narrow sheet NS. One side of the wide sheet WS contacting the data storage element CAP and one side of the second doped region DR may each have a flat side shape.

A horizontal length of the wide sheet WS in the second direction D2 may be less than that of the narrow sheet NS. The narrow sheet NS may be referred to as a “long sheet”, and the wide sheet WS may be referred to as a “short sheet”.

The nano-sheet HL may include a semiconductive material. For example, the nano-sheet HL may include polysilicon, monocrystalline silicon, germanium, or silicon-germanium. In an embodiment, the nano-sheet HL may include an oxide semiconductor material. For example, the oxide semiconductor material may include indium gallium zinc oxide (IGZO), InSnZnO, ZnSnO, or a combination thereof. In an embodiment, the nano-sheet HL may include conductive metal oxide. In an embodiment, the nano-sheet HL may include a two-dimensional material, for example, MoS₂, WS₂, or MoSe₂.

When the nano-sheet HL is formed of the oxide semiconductor material, the channel CH may also be formed of the oxide semiconductor material, and the first and second doped regions SR and DR may be omitted. The nano-sheet HL may also be referred to as an “active layer” or a “thin body”.

The first doped region SR and the second doped region DR may be doped with the same conductivity type of impurities. The first doped region SR and the second doped region DR may be doped with an N-type conductive impurity or a P-type conductive impurity. The first doped region SR and the second doped region DR may include at least one impurity selected from among arsenic (As), phosphorus (P), boron (B), indium (In), and combinations thereof. The first doped region SR may be electrically coupled to the first conductive line BL, and the second doped region DR may be electrically coupled to the data storage element CAP. The first and second doped regions SR and DR may be referred to as “first and second source/drain regions”.

The nano-sheet HL may be horizontally oriented in the second direction D2 from the first conductive line BL.

The second conductive line WL may have a gate all around structure (GAA). For example, the second conductive line WL may surround the nano-sheet HL and extend in the third direction D3. The nano-sheet dielectric layer GD may be formed between the nano-sheet HL and the second conductive line WL. The nano-sheet dielectric layer GD may surround the nano-sheet HL. The second conductive line WL may surround the channel CH of the nano-sheet HL on the nano-sheet dielectric layer GD.

The second conductive line WL may include a metal-based material, a semiconductive material, or a combination thereof. The second conductive line WL may include molybdenum, molybdenum nitride, ruthenium, titanium nitride, tungsten, polysilicon, or a combination thereof. For example, the second conductive line WL may include a TiN/W stack in which titanium nitride and tungsten are sequentially stacked. The second conductive line WL may include an N-type work function material or a P-type work function material. The N-type work function material may have a low work function of approximately 4.5 eV or lower, and the P-type work function material may have a high work function of approximately 4.5 eV or higher. The second conductive line WL may include a stack of the low work function material and the high work function material.

The nano-sheet dielectric layer GD may be disposed between the nano-sheet HL and the second conductive line WL. The nano-sheet dielectric layer GD may be referred to as a “gate dielectric layer” or a “channel-side dielectric layer”. The nano-sheet dielectric layer GD may include silicon oxide, silicon nitride, metal oxide, metal oxide nitride, metal silicate, a high-k material, a ferroelectric material, an anti-ferroelectric material, or a combination thereof. The nano-sheet dielectric layer GD may include SiO₂, Si₃N₄, HfO₂, Al₂O₃, ZrO₂, AlON, HfON, HfSIO, HfSiON, HfZrO, or a combination thereof. The nano-sheet dielectric layer GD may be formed by deposition of silicon oxide and thermal oxidation of the nano-sheet HL.

The data storage element CAP may include a memory element such as a capacitor. The data storage element CAP may be horizontally disposed in the second direction D2 from the switching element TR. The data storage element CAP may include a first electrode SN, a second electrode PN on the first electrode SN, and a dielectric layer DE between the first electrode SN and the second electrode PN. The first electrode SN may horizontally extend from the nano-sheet HL in the second direction D2. The first electrode SN, the dielectric layer DE and the second electrode PN may be horizontally disposed in the second direction D2. The first electrode SN may include an inner space and a plurality of outer surfaces, and the inner space of the first electrode SN may include a plurality of inner surfaces. The outer surfaces of the first electrode SN may include a vertical outer surface and a plurality of horizontal outer surfaces. The vertical outer surface of the first electrode SN may extend vertically in the first direction D1, and the horizontal outer surfaces of the first electrode SN may horizontally extend in the second direction D2 or the third direction D3. The inner space of the first electrode SN may be a three-dimensional space. The dielectric layer DE may conformally cover the inner surfaces of the first electrode SN. The second electrode PN may be disposed in the inner space of the first electrode SN on the dielectric layer DE. Some of the outer surfaces of the first electrode SN may be electrically coupled to the second doped region DR of the nano-sheet HL. The second electrode PN of the data storage element CAP may be coupled to a common plate PL.

The data storage element CAP may have a three-dimensional structure. The first electrode SN may have a three-dimensional structure, and the first electrode SN having the three-dimensional structure may have a horizontal three-dimensional structure that is oriented in the second direction D2. As an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically coupled to the second doped region DR of the nano-sheet HL. The dielectric layer DE and the second electrode PN may be disposed on the cylindrical inner surfaces and cylindrical outer surfaces of the first electrode SN. In an embodiment, the first electrode SN may have a semi-cylindrical shape. Specifically, the semi-cylindrical shape may refer to a structure in which the second electrode PN partially covers the outer surfaces of the first electrode SN.

In an embodiment, the first electrode SN may have a pillar shape or a pylinder shape. The pylinder shape may refer to a structure in which a pillar shape and a cylindrical shape are merged.

The first electrode SN and the second electrode PN may include metal, noble metal, metal nitride, conductive metal oxide, conductive noble metal oxide, metal carbide, metal silicide, or a combination thereof. For example, the first electrode SN and the second electrode PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TIN) stack, a titanium silicon nitride/titanium nitride/tungsten (TiSiN/TIN/W) stack, or a combination thereof. The second electrode PN may also include a combination of a metal-based material and a silicon-based material. For example, the second electrode PN may be a titanium nitride/silicon germanium/tungsten nitride (TiN/SiGe/WN) stack. In the titanium nitride/silicon germanium/tungsten nitride (TiN/SiGe/WN) stack, silicon germanium may be a gap-fill material that fills the inside of the first electrode SN, titanium nitride (TiN) may serve as the second electrode PN of the data storage element CAP, and tungsten nitride may be a low-resistance material.

The dielectric layer DE may be referred to as a “capacitor dielectric layer” or a “memory layer”. The dielectric layer DE may include silicon oxide, silicon nitride, a high-k material, a perovskite material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In an embodiment, the dielectric layer DE may be formed of a composite layer including two or more layers of the above-described high-k material.

The dielectric layer DE may be formed of zirconium (Zr)-based oxide. The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃) and zirconium oxide (ZrO₂) are sequentially stacked. Each of the ZA stack and the ZAZ stack may be referred to as a “zirconium oxide (ZrO₂)-based layer”. In an embodiment, the dielectric layer DE may be formed of hafnium (Hf)-based oxide. The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃) and hafnium oxide (HfO₂) are sequentially stacked. Each of the HA stack and the HAH stack may be referred to as a “hafnium oxide (HfO₂)-based layer”. In the ZA stack, ZAZ stack, HA stack and HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material having a greater band gap energy than the high-k material. The dielectric layer DE may include silicon oxide (SiO₂) as a high band gap material other than aluminum oxide (Al₂O₃). Since the dielectric layer DE includes a high band gap material, leakage current may be suppressed. The high band gap material may be thinner than the high-k material. In an embodiment, the dielectric layer DE may include a stack structure in which a high-k material and a high band gap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, a HZHZ (HfO₂/ZrO₂/HfO₂/ZrO₂) stack, or AHZAZHA (Al₂O₃/HfO₂/ZrO₂/Al₂O₃/ZrO₂/HfO₂/Al₂O₃) stack. In the above-described stack structures, aluminum oxide (Al₂O₃) may be thinner than zirconium oxide (ZrO₂) and hafnium oxide (HfO₂).

In an embodiment, the dielectric layer DE may include a high-k material and a high band gap material, and the dielectric layer DE may have a laminated structure in which a plurality of high-k materials and a plurality of high band gap materials are stacked, or an intermixed structure in which a high-k material and a high band gap material are intermixed.

In an embodiment, the dielectric layer DE may include a ferroelectric material, an anti-ferroelectric material, or a combination thereof. For example, the dielectric layer DE may include HfZrO.

In an embodiment, the dielectric layer DE may include a combination of a high-k material and a ferroelectric material, a combination of a high-k material and an anti-ferroelectric material, or a combination of a high-k material or a ferroelectric material and an anti-ferroelectric material.

In an embodiment, an interface control layer may be further formed between the first electrode SN and the dielectric layer DE to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced by another data storage material. For example, the data storage material may be a thyristor, a phase-change material, a Magnetic Tunnel Junction (MTJ), or a variable resistance material.

The memory cell MC may further include a first contact node BLC and a second contact node SNC. The first contact node BLC may be disposed between the first conductive line BL and the nano-sheet HL. The first contact node BLC may include a metal-based material or a semiconductive material. For example, the first contact node BLC may include titanium, titanium nitride, tungsten, or a combination thereof. In addition, the first contact node BLC may include doped polysilicon, and the first doped region SR may include an impurity diffused from the first contact node BLC. The second contact node SNC may be disposed between the nano-sheet HL and the first electrode SN. The second contact node SNC may include a metal-based material or a semiconductive material. For example, the second contact node SNC may include titanium, titanium nitride, tungsten, or a combination thereof. In addition, the second contact node SNC may include doped silicon, and the second doped region DR may include an impurity diffused from the second contact node SNC. The height of the first contact node BLC in the first direction D1 may be less than that of the second contact node SNC in the first direction D1. The height of the first contact node BLC in the first direction D1 may be greater than that of the channel CH in the first direction D1.

In an embodiment, the second contact node SNC may be selectively grown from the wide sheet WS of the nano-sheet HL. The second contact node SNC may be formed by selective epitaxial growth (SEG). For example, the second contact node SNC may be a silicon epitaxial layer formed by the selective epitaxial growth (SEG). The second contact node SNC may be a doped silicon epitaxial layer.

In an embodiment, the first contact node BLC may be selectively grown from the narrow sheet NS of the nano-sheet HL. The first contact node BLC may be formed by the selective epitaxial growth (SEG). For example, the first contact node BLC may be a silicon epitaxial layer formed by the selective epitaxial growth (SEG). The first contact node BLC may be a doped silicon epitaxial layer.

The first contact node BLC may be a narrow sheet-side contact node, and the second contact node SNC may be a wide sheet-side contact node.

The nano-sheet HL may include a first edge and a second edge. The first edge may refer to a portion of the first doped region SR electrically coupled to the first conductive line BL, and the second edge may refer to a portion of the second doped region DR electrically coupled to the first electrode SN of the data storage element CAP.

The memory cell MC may further include an ohmic contact layer BLO between the first contact node BLC and the first conductive line BL. The ohmic contact layer BLO may include metal silicide. In an embodiment, the memory cell MC may further include an ohmic contact layer formed between the second contact node SNC and the first electrode SN of the data storage element CAP. The first conductive line BL, the ohmic contact layer BLO, the first contact node BLC and the first doped region SR may be electrically coupled to one another. The second doped region DR, the second contact node SNC and the first electrode SN of the data storage element CAP may be electrically coupled to one another.

The memory cell MC may further include a first spacer SP1 and a second spacer SP2. The first spacer SP1 may be disposed between the second conductive line WL and the first doped region SR. The second spacer SP2 may be disposed between the second conductive line WL and the second doped region DR. The first and second spacers SP1 and SP2 may extend in the third direction D3 while surrounding the nano-sheet HL. That is, the first and second spacers SP1 and SP2 may surround the nano-sheet HL while being disposed on both sidewalls of the second conductive line WL.

A first inter-cell horizontal dielectric layer CIL1 may be formed between the second spacer SP2 and the first conductive line BL. A portion of the first inter-cell horizontal dielectric layer CIL1 may be disposed between the first spacer SP1 and the first conductive line BL. A second inter-cell horizontal dielectric layer CIL2 may be disposed between the first electrodes SN of the data storage elements CAP The second inter-cell horizontal dielectric layer CIL2 may extend from the second spacer SP2 toward the data storage element CAP. The second inter-cell horizontal dielectric layer CIL2 and the second spacer SP2 may be made of the same material and form an integral part. For example, the first and second inter-cell horizontal dielectric layers CIL1 and CIL2 may each include silicon oxide, silicon carbon oxide (SiCO), silicon nitride, or a combination thereof. The first inter-cell horizontal dielectric layer CIL1 may include a stack of a first liner L1, a second liner L2 and a third liner L3. The first liner L1 may contact the second conductive line WL, the second liner L2, and the second spacer SP2. The second liner L2 may contact the first conductive line BL. The second liner L2 may also contact the ohmic contact layer BLO, and the first contact note BLC. The third liner L3 may be disposed between the first conductive line BL and the second liner L2. The third liner L3 may partially fill an inner portion of the second liner L2. A portion of the second liner L2 may fill an inner portion of the first liner L1.

The first conductive line BL may include a plurality of horizontal extension portions. The horizontal extension portions may extend in the second direction D2. The horizontal extension portions may include an inner horizontal extension portion and outer horizontal extension portions. The inner horizontal extension portion of the first conductive line BL may be disposed in a gap formed between a pair of adjacent second liners L2 of the first inter-cell horizontal dielectric layer CIL1 disposed vertically adjacent to each other. Accordingly, the inner horizontal extension portion of the first conductive line BL may be electrically coupled to the ohmic contact layer BLO. The outer horizontal extension portions of the first conductive line BL may extend to be disposed in one side of the first inter-cell horizontal dielectric layer CIL1. Accordingly, the outer horizontal extension portions may contact the third liner L3 of the first inter-cell horizontal dielectric layer CIL1. In an embodiment, the outer horizontal extension portions of the first conductive line BL may be omitted.

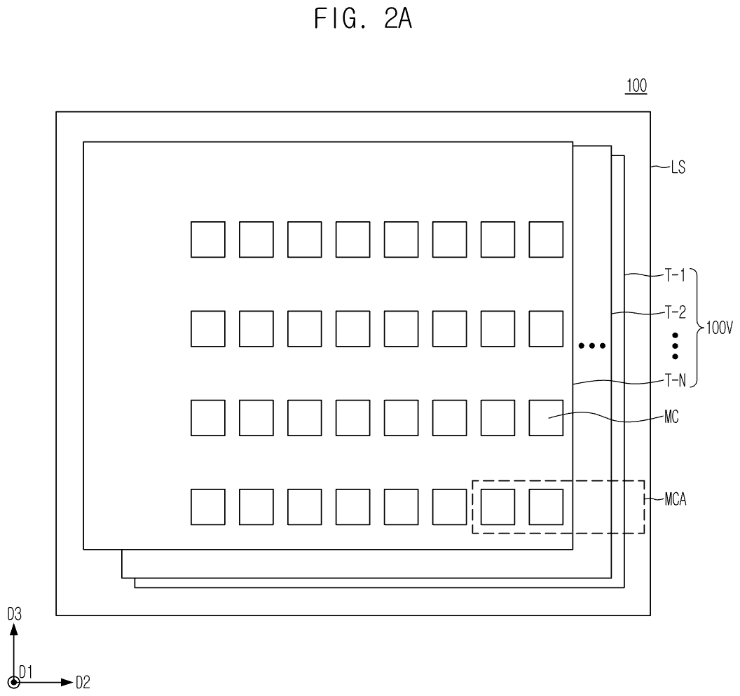

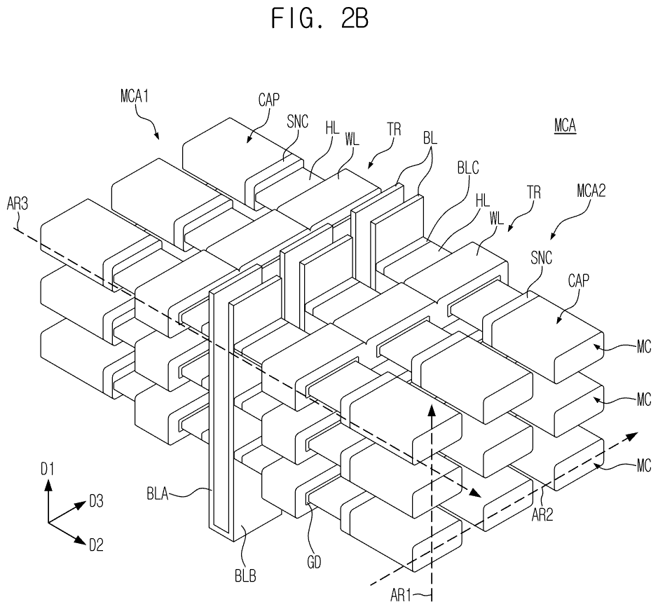

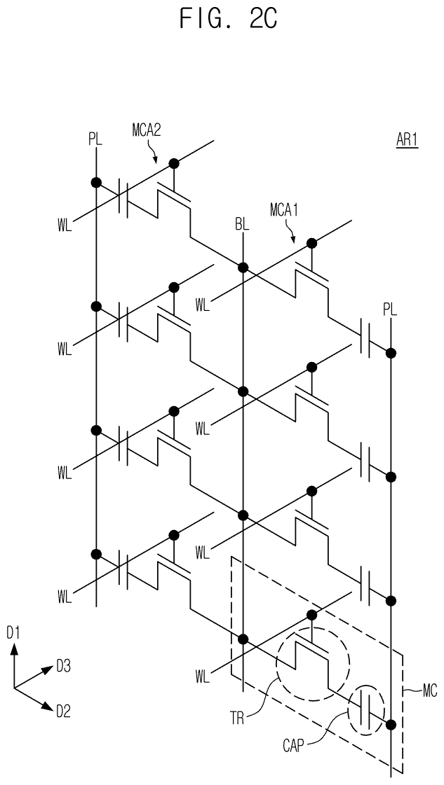

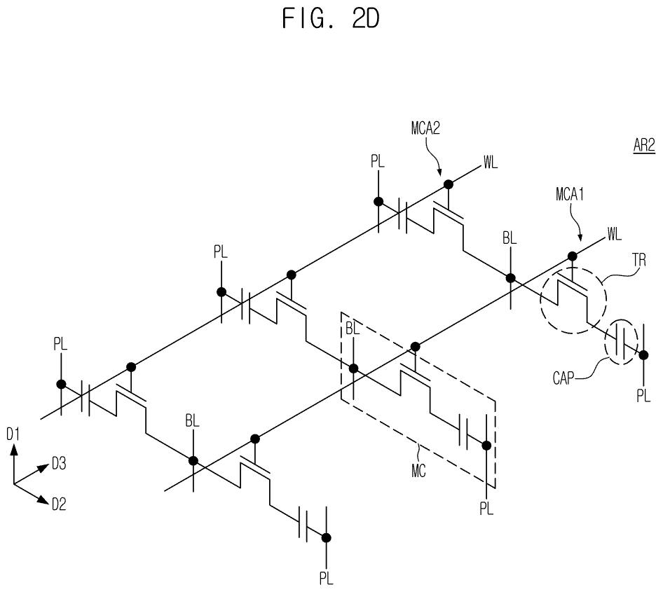

FIG. 2A is a schematic view illustrating a semiconductor device 100 in accordance with an embodiment of the present disclosure. FIG. 2B is a schematic perspective view illustrating a memory cell array MCA illustrated in FIG. 2A. FIG. 2C is an equivalent circuit view of a column array AR1 illustrated in FIG. 2B. FIG. 2D is an equivalent circuit view of a row array AR2 illustrated in FIG. 2B.

Referring to FIG. 2A, the semiconductor device 100 may include a plurality of planes T-1 to T-N. The planes T-1 to T-N may constitute a vertical stack 100V. Each of the planes T-1 to T-N may include a plurality of memory cells MC. The vertical stack 100V may include a memory cell array MCA, and the memory cell array MCA may include a three-dimensional array of the memory cells MC. Detailed components of the memory cells MC are described above with reference to FIGS. 1A and 1B.

Referring to FIGS. 2B to 2D, the memory cell array MCA may include the plurality of memory cells MC vertically stacked in a first direction D1. The memory cell array MCA may include the plurality of memory cells MC horizontally disposed in a second direction D2. The memory cell array MCA may include the plurality of memory cells MC horizontally disposed in a third direction D3.

Each of the memory cells MC may include a first conductive line BL, a switching element TR, and a data storage element CAP, and the switching element TR may include a second conductive line WL, a nano-sheet dielectric layer GD, and a nano-sheet HL.

The memory cell array MCA may include the column array AR1 of the memory cells MC and the row array AR2 of the memory cells MC. The column array AR1 may include the plurality of memory cells MC vertically stacked in a first direction D1. The memory cells MC in the column array AR1 may share a first conductive line BL. The row array AR2 may include the plurality of memory cells MC horizontally disposed in a third direction D3. The memory cells MC in the row array AR2 may share a second conductive line WL. The first direction D1 may be a vertical direction, and the third direction D3 may be a horizontal direction. The memory cell array MCA may further include a horizontal level array AR3, and the horizontal level array AR3 may include the plurality of memory cells MC disposed at the same horizontal level in a second direction D2. Neighboring memory cells MC in the horizontal level array AR3 may share a first conductive line BL.

The memory cell array MCA may include a first sub-cell array MCA1 and a second sub-cell array MCA2. The first sub-cell array MCA1 and the second sub-cell array MCA2 may each include a three-dimensional array of the memory cells MC. The first sub-cell array MCA1 and the second sub-cell array MCA2 may share a first conductive line BL. The first conductive line BL may include a first vertical conductive line BLA and a second vertical conductive line BLB, and a bottom portion of the first vertical conductive line BLA and a bottom portion of the second vertical conductive line BLB may be merged with each other. The first conductive line BL may have a U-shape formed by the merging of the first vertical conductive line BLA and the second vertical conductive line BLB. The memory cells MC of the first sub-cell array MCA1 may share a first vertical conductive line BLA, and the memory cells MC of the second sub-cell array MCA2 may share a second vertical conductive line BLB. In this way, the neighboring first and second sub-cell arrays MCA1 and MCA2 may have a mirror-shaped structure of sharing the first conductive line BL. From the perspective of a top view, the first and second vertical conductive lines BLA and BLB may have a rectangular shape.

Referring back to FIG. 2A, a lower structure LS may be disposed at a lower level than the memory cell array MCA. The lower structure LS may include a semiconductor substrate, a metal interconnection structure, a dielectric structure, a conductive structure, a bonding pad structure, another memory, or a peripheral circuit portion. For example, the lower structure LS may include a structure in which the peripheral circuit portion, the metal interconnection structure, and the bonding pad structure are sequentially stacked. The memory cell array MCA and the peripheral circuit portion of the lower structure LS may be bonded by wafer bonding. The wafer bonding may include pad bonding, hybrid bonding, oxide-to-oxide bonding, metal-to-metal bonding, or a combination thereof.

The peripheral circuit portion of the lower structure LS may be disposed at a lower level than the memory cell array MCA. This may be referred to as a “cell array over PERI (COP) structure” or a “PERI under cell array (PUC) structure”. The peripheral circuit portion may include at least one control circuit for driving the memory cell array MCA. At least one control circuit of the peripheral circuit portion may include an N-channel transistor, a P-channel transistor, a CMOS circuit, or a combination thereof. At least one control circuit of the peripheral circuit portion may include an address decoder circuit, a read circuit, or a write circuit. At least one control circuit of the peripheral circuit portion may include a planar channel transistor, a recess channel transistor, a buried gate transistor, or a fin channel transistor (FinFET).

For example, the peripheral circuit portion may include sub-word line drivers and a sense amplifier. The first conductive line BL may be coupled to the sense amplifier, and the second conductive lines DWL may be coupled to the sub-word line drivers.

In an embodiment, the peripheral circuit portion may be disposed at a higher level than the memory cell array MCA. This may be referred to as a “PERI over cell (POC) structure” or a “cell array under PERI (CUP) structure”.

In an embodiment, the memory cell array MCA may include a DRAM, embedded DRAM, NAND, FeRAM, STTRAM, PCRAM, or ReRAM.

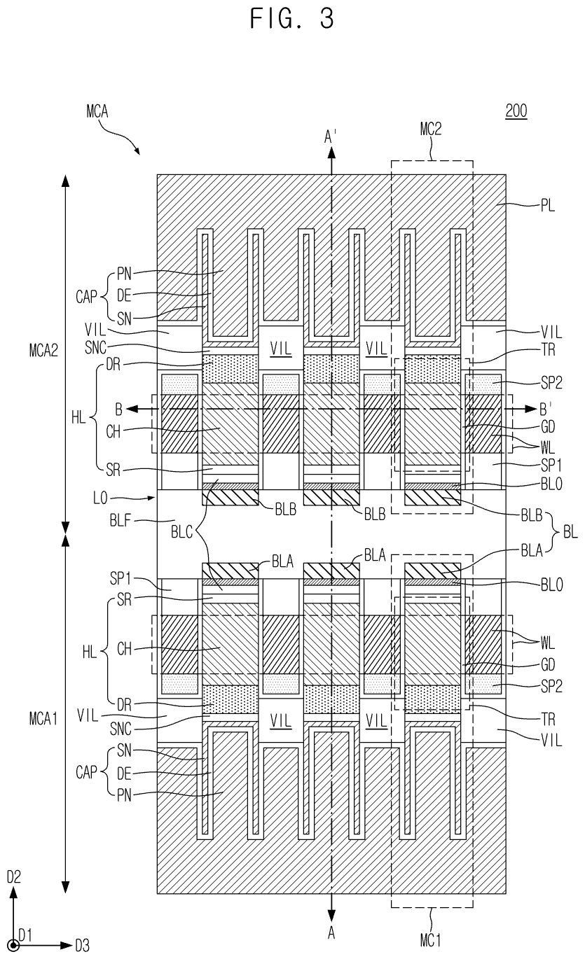

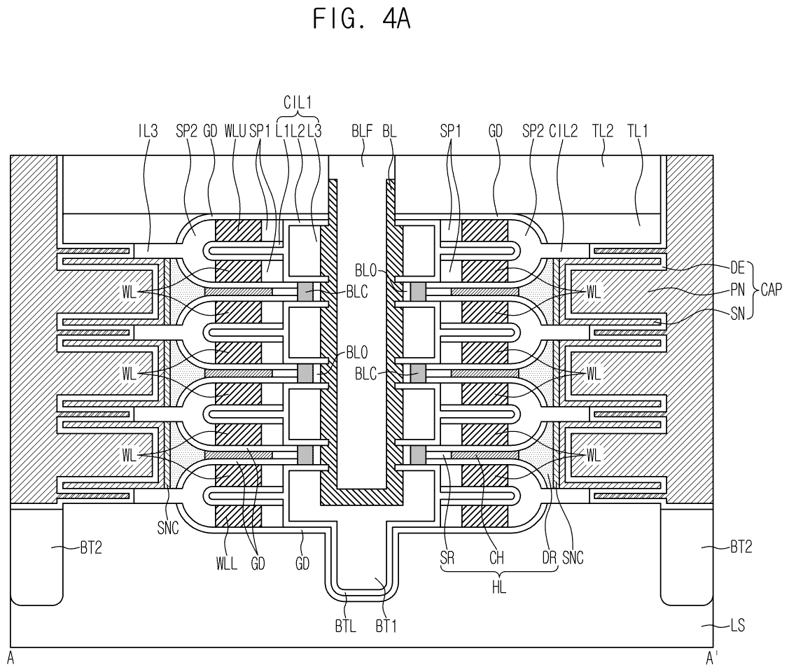

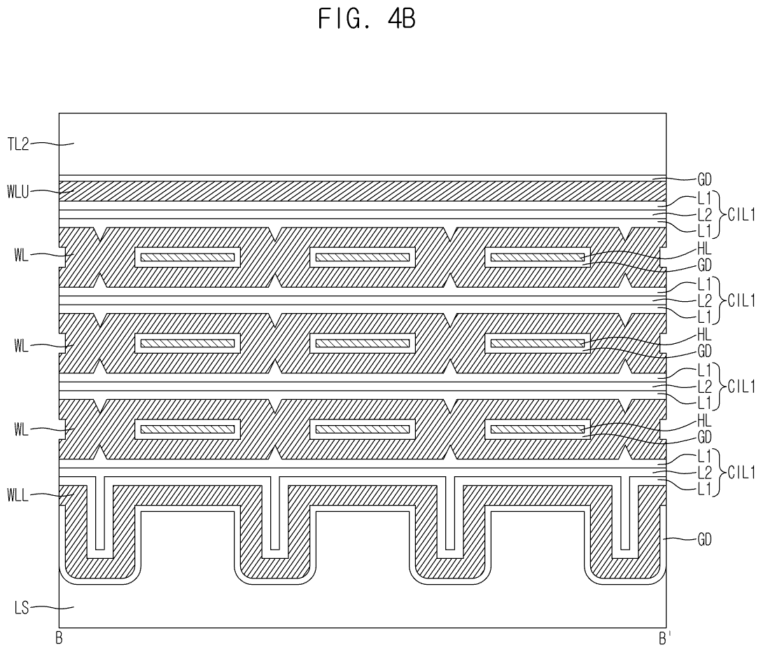

FIG. 3 is a schematic plan view illustrating a semiconductor device 200 in accordance with an embodiment of the present disclosure. FIG. 3 may be the plan view illustrating the semiconductor device 200 for describing the row array AR2 illustrated in FIG. 2B. FIG. 4A is a cross-sectional view of the semiconductor device 200 taken along line A-A′ illustrated in FIG. 3. FIG. 4B is a cross-sectional view of the semiconductor device 200 taken along line B-B′ illustrated in FIG. 3.

The semiconductor device 200 illustrated in FIGS. 3, 4A and 4B may be similar to the memory cell array MCA described above with the reference to FIGS. 2A to 2D. Hereinafter, detailed descriptions of overlapping components are omitted.

Referring to FIGS. 3, 4A and 4B, the semiconductor device 200 may include a memory cell array MCA, and the memory cell array MCA may include a three-dimensional array of memory cells MC1 and MC2. The memory cell array MCA may include a first sub-cell array MCA1 and a second sub-cell array MCA2.

The memory cell array MCA may include a plurality of memory cells MC1 and MC2 vertically stacked in a first direction D1. The memory cells MC1 and MC2 may each have the same configuration as the memory cell MC described with reference to FIGS. 1A and 1B. The memory cell array MCA may include a plurality of memory cells MC1 and MC2 horizontally disposed in a second direction D2. The memory cell array MCA may include a plurality of memory cells MC1 and MC2 horizontally disposed in a third direction D3. The memory cell array MCA may include a plurality of first conductive lines BL, each of the first conductive lines BL may include a first vertical conductive line BLA and a second vertical conductive line BLB, and a bottom portion of the first vertical conductive line BLA may be merged with a bottom portion of the second vertical conductive line BLB.

The first memory cell MC1 of the first sub-cell array MCA1 may include the first vertical conductive line BLA, a switching element TR, and a data storage element CAP. The switching element TR may include a second conductive line WL and a nano-sheet HL. The second memory cell MC2 of the second sub-cell array MCA2 may include the second vertical conductive line BLB, a switching element TR, and a data storage element CAP, and the switching element TR may include a second conductive line WL and a nano-sheet HL. The switching elements TR of the first and second memory cells MC1 and MC2 may be nano-sheet transistors.

The first conductive line BL may extend vertically in the first direction D1, the nano-sheet HL may extend in the second direction D2, and the second conductive line WL may horizontally extend in the third direction D3.

A vertical inter-cell dielectric layer VIL may be disposed between the data storage elements CAP disposed adjacent to each other in the third direction D3. A first inter-cell horizontal dielectric layer CIL1 may be disposed between the second conductive lines WL vertically stacked in the first direction D1. A second inter-cell horizontal dielectric layer CIL2 may be disposed between first electrodes SN of the data storage elements CAP vertically stacked in the first direction D1. The vertical inter-cell dielectric layer VIL and the first and second inter-cell horizontal dielectric layers CIL1 and CIL2 may each include silicon oxide, silicon carbon oxide (SiCO), silicon nitride, or a combination thereof. The vertical inter-cell dielectric layer VIL may be referred to as a “device isolation layer”.

Each of the memory cells MC1 and MC2 may further include a first contact node BLC and a second contact node SNC. The first contact node BLC may be disposed between the first conductive lines BLA and BLB and the nano-sheet HL. The first contact node BLC may include a metal-based material or a semiconductive material. For example, the first contact node BLC may include titanium, titanium nitride, tungsten, or a combination thereof. In addition, the first contact node BLC may include doped epitaxial silicon or doped polysilicon, and a first doped region SR may include an impurity diffused from the first contact node BLC. The second contact node SNC may be disposed between the nano-sheet HL and the first electrode SN. The second contact node SNC may include a metal-based material or a semiconductive material. For example, the second contact node SNC may include titanium, titanium nitride, tungsten, or a combination thereof. In addition, the second contact node SNC may include doped epitaxial silicon or doped polysilicon, and a second doped region DR may include an impurity diffused from the second contact node SNC. The height of the first contact node BLC in the first direction D1 may be less than that of the second contact node SNC in the first direction D1. The height of the first contact node BLC in the first direction D1 may be greater than that of the channel CH in the first direction D1.

Each of the memory cells MC1 and MC2 may further include an ohmic contact layer BLO between the first contact node BLC and the first conductive line BL. The ohmic contact layer BLO may include metal silicide.

Each of the memory cells MC1 and MC2 may further include a first and second spacers SP1 and SP2. The first spacer SP1 may be disposed between the second conductive line WL and the first doped region SR. The second spacer SP2 may be disposed between the second conductive line WL and the second doped region DR. The second spacer SP2 may cover one side of the first inter-cell horizontal dielectric layer CIL1. The second spacer SP2 may have a cup shape, for example, a “>” shape. The first and second spacers SP1 and SP2 may surround the nano-sheets HL spaced apart from each other along the third direction D3. The first spacer SP1 may be disposed on one side of the second conductive line WL and extend in the third direction D3. The second spacer SP2 may be disposed on the other side of the second conductive line WL and extend in the third direction D3.

The first inter-cell horizontal dielectric layer CIL1 may be disposed between the first spacer SP1 and the first conductive line BL. The second inter-cell horizontal dielectric layer CIL2 may be disposed between the first electrodes SN of the data storage elements CAP. The second inter-cell dielectric layer CIL2 may extend from the second spacer SP2. The second inter-cell horizontal dielectric layer CIL2 and the second spacer SP2 may be integral. The first and second inter-cell horizontal dielectric layers CIL1 and CIL2 may each include silicon oxide, silicon carbon oxide (SiCO), silicon nitride, or a combination thereof.

The first inter-cell horizontal dielectric layer CIL1 may include a stack of a first liner L1, a second liner L2 and a third liner L3. The first liner L1 may contact the second conductive line WL, and the second liner L2 may contact the first conductive line BL. The third liner L3 may be disposed between the first conductive line BL and the second liner L2. The third liner L3 may partially fill an inner portion of the second liner L2. A portion of the second liner L2 may fill an inner portion of the first liner L1.

Referring back to FIG. 4B, the first inter-cell horizontal dielectric layer CIL1 may be disposed between the second conductive lines WL arranged vertically.

The memory cell array MCA may include a plurality of second conductive lines WL vertically stacked in the first direction D1. The memory cell array MCA may include a plurality of nano-sheets HL vertically stacked in the first direction D1. The memory cell array MCA may include a plurality of data storage elements CAP vertically stacked in the first direction D1. The memory cell array MCA may include a plurality of first conductive lines BL spaced apart in the third direction D3. The memory cell array MCA may include dummy second conductive lines WLU and WLL disposed at a level higher than an uppermost second conductive line WL and at a level lower than a lowermost second conductive line WL, respectively. The dummy second conductive lines WLU and WLL may each have a linear shape extending horizontally.

The memory cell array MCA may include a stack of a plurality of hard mask layers TL1 and TL2 disposed at a level higher than the uppermost second conductive line WL.

The memory cell array MCA may include a plurality of first and second bottom protection layers BT1 and BT2. The first bottom protection layer BT1 may prevent a bottom surface of the first conductive line BL from being in electrical contact with a lower structure LS. The second bottom protection layer BT2 may prevent the data storage element CAP from being in electrical contact with the lower structure LS. A dummy liner BTL and a nano-sheet dielectric layer GD may be disposed between the first bottom protection layer BT1 and the lower structure LS.

A vertical isolation layer BLF may be disposed between the first and second vertical conductive lines BLA and conductive line BLB of the first conductive line BL. The vertical isolation layer BLF may include a dielectric material.

The nano-sheets HL of the switching elements TR horizontally disposed in the third direction D3 may share one second conductive line WL. The nano-sheets HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line WL.

Second electrodes PN of the data storage elements CAP may be coupled to a common plate PL.

In an embodiment described above, the semiconductor device 200 may include a column array and a row array of the nano-sheets HL, the second conductive lines WL surrounding in common the nano-sheets HL in the row array and respectively surrounding the nano-sheets HL in the column array, the data storage elements CAP respectively coupled to the nano-sheets HL in the column array and the row array, and the first conductive lines BL coupled in common to the nano-sheets HL in the column array. Each of the first conductive lines BL may include the first vertical conductive line BLA and the second vertical conductive line BLB, and the first vertical conductive line BLA and the second vertical conductive line BLB may be formed by mask and etch processes.

From another perspective, the semiconductor device 200 may include the first sub-cell array MCA1 including the first memory cells MC1 vertically stacked, the second sub-cell array MCA2 including the second memory cells MC2 vertically stacked, a linear opening (refer to reference symbol “LO” in FIG. 3) between the first sub-cell array MCA1 and the second sub-cell array MCA2, and the first conductive line BL formed in the linear opening LO and electrically coupled to the first and second memory cells MC1 and MC2 horizontally disposed adjacent to each other.

From another perspective, the semiconductor device 200 may include the first conductive line BL vertically oriented in the first direction D1, the data storage element CAP horizontally spaced apart from the first conductive line BL, the nano-sheet HL horizontally oriented in the second direction D2 perpendicular to the first direction D1 and including a first region NS in contact with the first conductive line BL and a second region WS in contact with the data storage element CAP, and the second conductive line WL extending while surrounding the nano-sheet HL in the third direction D3 perpendicular to the first and second directions D1 and D3.

From another perspective, the semiconductor device 200 may include a vertical stack including the column array AR1 of nano-sheet transistors TR vertically stacked in the first direction D1, wherein each of the nano-sheet transistors TR may include the nano-sheet HL including a flat plate-shaped narrow sheet NS and a fan-shaped wide sheet WS having a smaller horizontal length than the flat plate-shaped narrow sheet NS and extending in the second direction D2 perpendicular to the first direction D1 and the second conductive line WL surrounding the flat plate-shaped narrow sheet NS and horizontally oriented in the third direction D3 perpendicular to the first and second directions D1 and D2.

From another perspective, the semiconductor device 200 may include a first column array MCA1 of the nano-sheet transistors TR vertically stacked in the first direction D1, a second column array MCA2 of the nano-sheet transistors TR horizontally spaced apart from the first column array MCA1 and vertically stacked in the first direction D1, the vertical conductive line BL sharing the nano-sheet transistors TR in the first column array MCA1 and the nano-sheet transistors TR in the second column array MCA2 and extending in the first direction D1, and the data storage elements CAP coupled to the nano-sheet transistors TR of the first and second column arrays MCA1 and MCA2, wherein each of the nano-sheet transistors TR may include the nano-sheet HL including a flat plate-shaped narrow sheet NS and a fan-shaped wide sheet WS having a smaller horizontal length than the flat plate-shaped narrow sheet NS and extending in the second direction D2 perpendicular to the first direction D1 and the second conductive line WL surrounding the flat plate-shaped narrow sheet NS and horizontally oriented in the third direction D3 perpendicular to the first and second directions D1 and D2. The second conductive lines WL in the first and second column arrays MCA1 and MCA2 may extend in the third direction D3 while surrounding the nano-sheets HL at the same horizontal level.

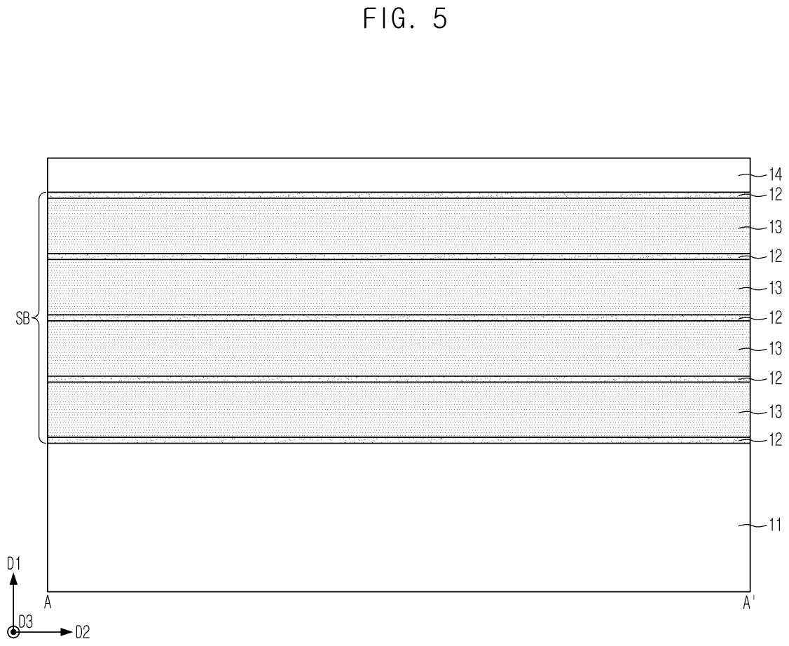

FIGS. 5 to 30 illustrate various views of a semiconductor device formed utilizing a method for fabricating the semiconductor device in accordance with an embodiment of the present disclosure.

As illustrated in FIG. 5, a mold stack SB may be formed on a substrate 11. The mold stack SB may include an alternating stack of first mold layers 12 and second mold layers 13.

The first mold layers 12 may be alternately stacked with the second mold layers 13, and the first mold layers 12 and the second mold layers 13 may be epitaxially grown multiple times, to form the mold stack SB.

The first mold layers 12 and the second mold layers 13 may be different semiconductor materials. The first mold layers 12 may include silicon germanium or monocrystalline silicon germanium. The second mold layers 13 may include monocrystalline silicon. The first mold layers 12 and the second mold layers 13 may be formed by an epitaxial growth process. A lowermost first mold layer 12 may serve as a seed layer during the epitaxial growth process. The first mold layers 12 may be thinner than the second mold layers 13. The first mold layers 12 may include first epitaxially grown layers, and the second mold layers 13 may include second epitaxially grown layers.

In an embodiment, a plurality of monocrystalline silicon germanium layers may be alternately stacked with a plurality of monocrystalline silicon layers in the mold stack SB. For example, the first mold layers 12 may be the monocrystalline silicon germanium layers, and the second mold layers 13 may be the monocrystalline silicon layers. A stack of a monocrystalline silicon germanium layer/a monocrystalline silicon layer (SiGe/Si stack) may be stacked multiple times. The first mold layers 12 may be referred to as “sacrificial layers”, and the second mold layers 13 may be referred to as “nano-sheet target layers” or “recess target layers”.

The mold stack SB may be referred to as a “vertical stack”. The mold stack SB may be formed by alternately stacking a plurality of sacrificial layers and a plurality of nano-sheet target layers. The sacrificial layers may be monocrystalline silicon germanium layers, and the nano-sheet target layers may be monocrystalline silicon layers.

A thickness ratio of the first mold layers 12 and the second mold layers 13 in the mold stack SB may be variously modified. For example, the thickness of the first mold layers 12 may be approximately 5 to 19 nm, and the thickness of the second mold layers 13 may be approximately 50 to 80 nm. A quantity of layers of the first mold layers 12 and the second mold layers 13 in the mold stack SB may be variously modified. In an embodiment, a triple stack including the first mold layer 12/the second mold layer 13/the first mold layer 12 may be defined at the lowermost and/or uppermost portions of the mold stack SB. The second mold layer 13 of the triple stack may have a smaller thickness than the second mold layer 13 of the mold stack SB.

A first hard mask layer 14 may be formed on the mold stack SB. The first hard mask layer 14 may include a dielectric material such as an oxide-based material, a nitride-based material, a carbon-based material, or a combination thereof. For example, the first hard mask layer 14 may include SiO₂, Si₃N₄, amorphous carbon, or a combination thereof.

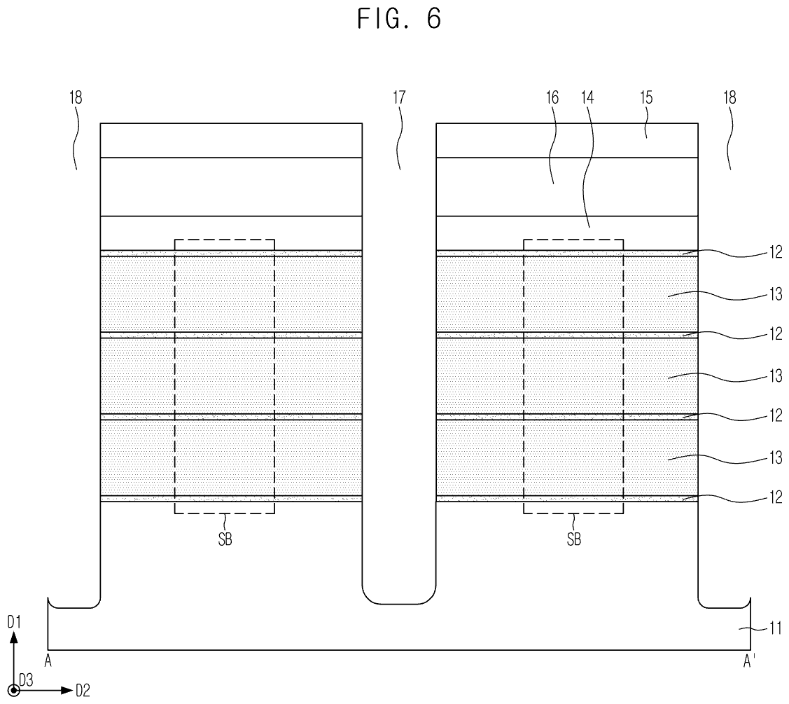

As illustrated in FIG. 6, a second hard mask layer 16 may be formed on the mold stack SB. The second hard mask layer 16 may include silicon nitride. The second hard mask layer 16 may be formed by etching a second hard mask material using a mask layer 15 such as photoresist. The second hard mask layer 16 may have a plurality of line-shaped openings defined therein.

Portions of the mold stack SB may be etched using the second hard mask layer 16 as an etch barrier. Accordingly, a plurality of sacrificial linear openings 17 and 18 may be formed. The sacrificial linear openings 17 and 18 may include a first sacrificial linear opening 17 and a second sacrificial linear opening 18. From the perspective of a top view, the first sacrificial linear opening 17 and the second sacrificial linear opening 18 may be line-shaped openings extending in a third direction D3. The first sacrificial linear opening 17 and the second sacrificial linear opening 18 may extend vertically in a first direction D1. A sacrificial isolation layer may be disposed between the first sacrificial linear opening 17 and the second sacrificial linear opening 18 in a second direction D2. From the perspective of a top view, cross-sections of the first and second sacrificial linear openings 17 and 18 may each have a rectangular shape. In an embodiment, the cross-sections of the first and second sacrificial linear openings 17 and 18 may each have a circular shape or an oval shape. The first and second sacrificial linear openings 17 and 18 may have a width in the second direction D2 less than a width in the third direction D3. The first and second sacrificial linear openings 17 and 18 may be referred to as “sacrificial isolation trenches”. The first and second sacrificial linear openings 17 and 18 may not contact the sacrificial isolation layer 16.

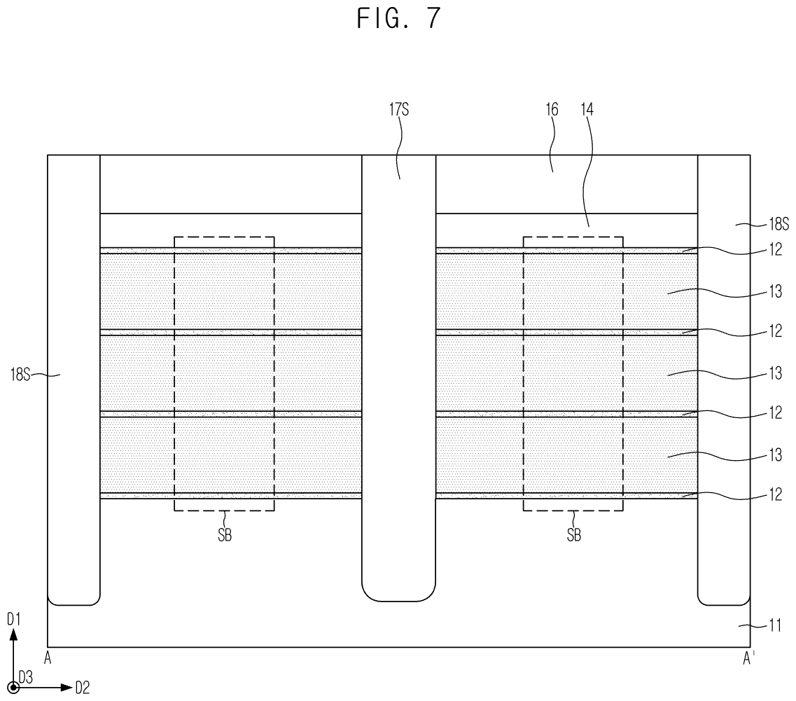

As illustrated in FIG. 7, linear sacrificial layers 17S and 18S may be formed to fill the first and second sacrificial linear openings 17 and 18. The linear sacrificial layers 17S and 18S may include a first linear sacrificial layer 17S and a second linear sacrificial layer 18S. From the perspective of a top view, the first linear sacrificial layer 17S and the second linear sacrificial layer 18S may have line shapes extending in the third direction D3. The first linear sacrificial layer 17S and the second linear sacrificial layer 18S may extend vertically in the first direction D1. From the perspective of a top view, cross sections of the first and second linear sacrificial layers 17S and 18S may each have a rectangular shape. In an embodiment, the cross-sections of the first and second linear sacrificial layers 17S and 18S may each have a circular shape or an oval shape. The first and second linear sacrificial layers 17S and 18S may include the same material. The first and second linear sacrificial layers 17S and 18S may be formed of a dielectric material. For example, the first and second linear sacrificial layers 17S and 18S may include silicon oxide, silicon nitride, silicon carbon oxide, silicon carbon nitride, or a combination thereof.

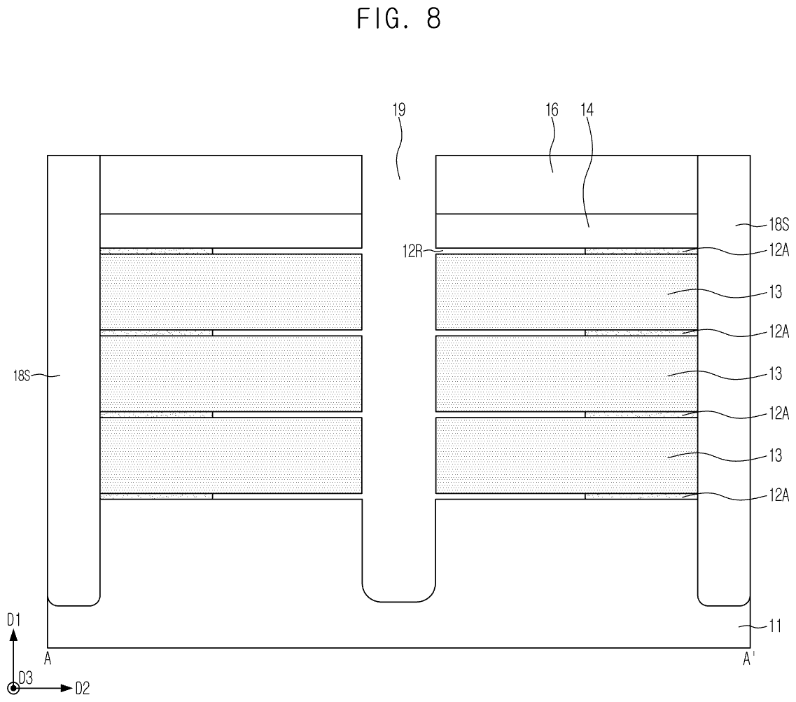

As illustrated in FIG. 8, among the first linear sacrificial layer 17S and the second linear sacrificial layer 18S, the first linear sacrificial layer 17S may be selectively removed. Accordingly, a first linear opening 19 may be formed. From the perspective of a top view, the first linear opening 19 may be disposed horizontally spaced apart from the second linear sacrificial layer 18S in the second direction D2.

The first mold layers 12 may be selectively recessed through the first linear opening 19. To selectively recess the first mold layers 12 (refer to reference numeral “12R”), a difference in etch selectivity between the first mold layers 12 and the second mold layers 13 may be used. The first mold layers 12 may be removed using a wet or a dry etch process. For example, when the first mold layers 12 include silicon germanium layers and the second mold layers 13 include monocrystalline silicon layers, the silicon germanium layers may be etched using an etchant or etch gas having a selectivity with respect to the monocrystalline silicon layers. The first mold layers having an original thickness may remain as indicated by reference numeral “12A”.

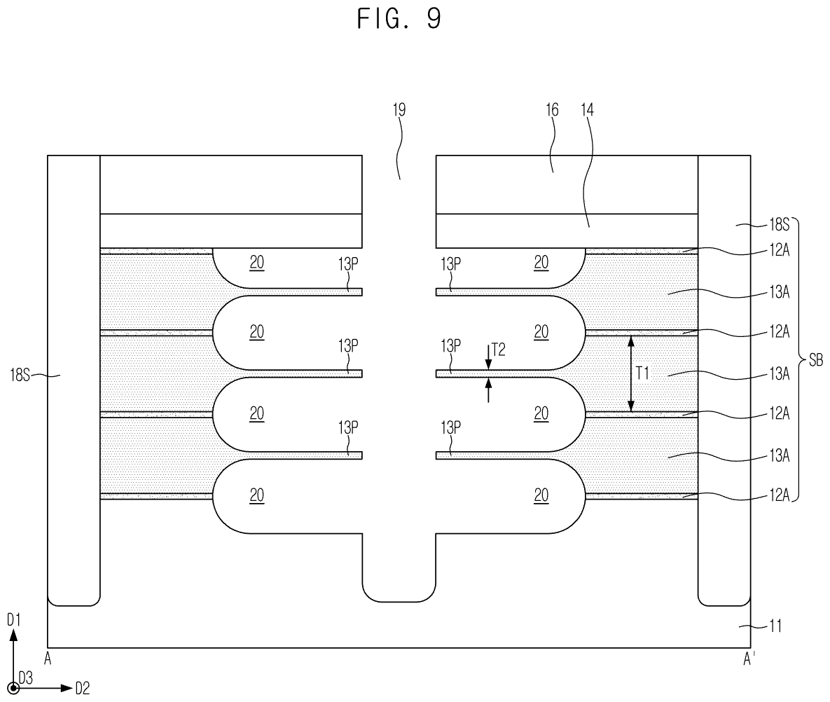

As illustrated in FIG. 9, a portion (a first portion) of each of the second mold layers 13 may be recessed to form a narrow sheet 13P. The wet etch process or dry etch process may be used to recess the second mold layer 13. An original body portion 13A and the narrow sheet 13P may be formed by the partial recessing of the second mold layer 13. The original body portion 13A may maintain an original thickness T1, and the narrow sheet 13P may have a thickness T2 less than the original thickness T1. A horizontal length of the original body portion 13A in the second direction D2 may be equal to or different from one of the narrow sheet 13P in the second direction D2. A combination of the original body portion 13A and the narrow sheet 13P may be referred to as a “preliminary nano-sheet”. The narrow sheet 13P may be referred to as a “flat plate-shaped sheet” or a “protruding narrow sheet”.

A recess process for forming the narrow sheet 13P may be referred to as a “thinning process” or “trimming process” of the second mold layer 13. To form the narrow sheet 13P, an upper surface, lower surface and side surface of the second mold layer 13 may be recessed. The narrow sheet 13P may be referred to as a “thin-body active layer”. The narrow sheet 13P may include a monocrystalline silicon layer. The recess process for forming the narrow sheets 13P may use, for example, Hot SC-1 (HSC1). The HSC1 may include a solution in which ammonium hydroxide (NH₄OH), hydrogen peroxide (H₂O₂) and water (H₂O) are mixed in a ratio of 1:4:19. Using the HSC1, the second mold layers 13 may be selectively etched.

The narrow sheets 13P may be formed by the partial recess process for the second mold layers 13 as described above, and an inter-nano-sheet recess 20 may be formed between the narrow sheets 13P that are vertically disposed. Upper and lower surfaces of the narrow sheets 13P may each include a flat surface. A boundary portion between the original body portion 13A and the narrow sheet 13P may be vertical or have a curvature. Each of the first mold layers 12A may be disposed between the original body portions 13A that are vertically stacked.

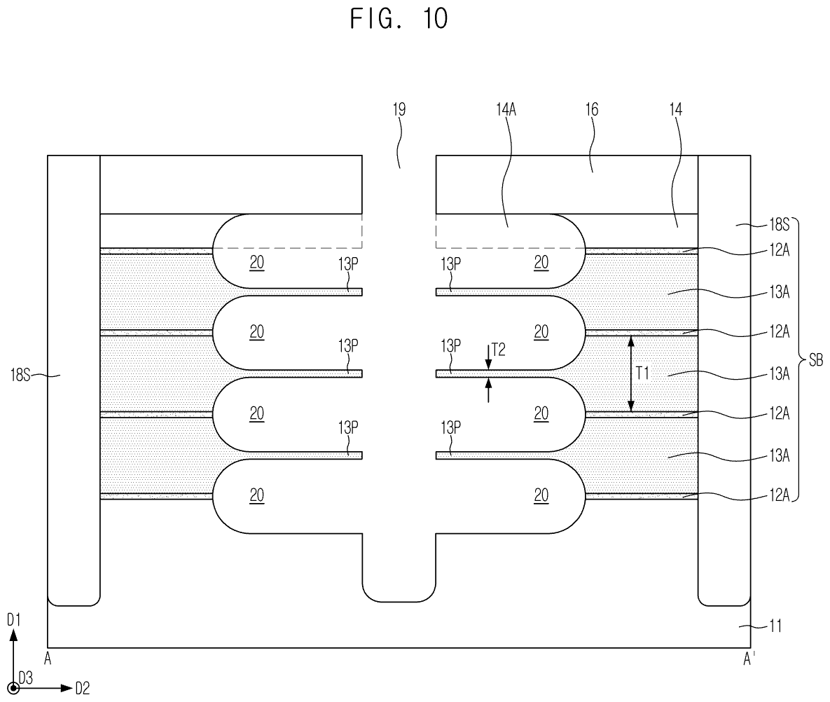

As illustrated in FIG. 10, a portion of the first hard mask layer 14 (refer to reference numeral “14A”) may be recessed through the inter-nano-sheet recesses 20. Accordingly, a space of an uppermost inter-nano-sheet recess 20 may be expanded.

Subsequently, a process of forming vertical inter-cell dielectric layers VIL described with reference to FIG. 3 may be performed. For example, the process may include removing sacrificial isolation layers to form cell isolation openings and forming the vertical inter-cell dielectric layers VIL in the cell isolation openings. The vertical inter-cell dielectric layers VIL may include silicon oxide, silicon nitride, silicon carbon oxide, silicon carbon nitride, or a combination thereof. Each of the vertical inter-cell dielectric layers VIL may include a stack of a cell isolation liner and a cell isolation gap-fill layer. The cell isolation liner may be silicon nitride, and the cell isolation gap-fill layer may be silicon oxide or silicon carbon oxide. During the formation of the vertical inter-cell dielectric layers VIL, the portion 14A of the first hard mask layer 14 may be recessed, as illustrated in FIG. 10.

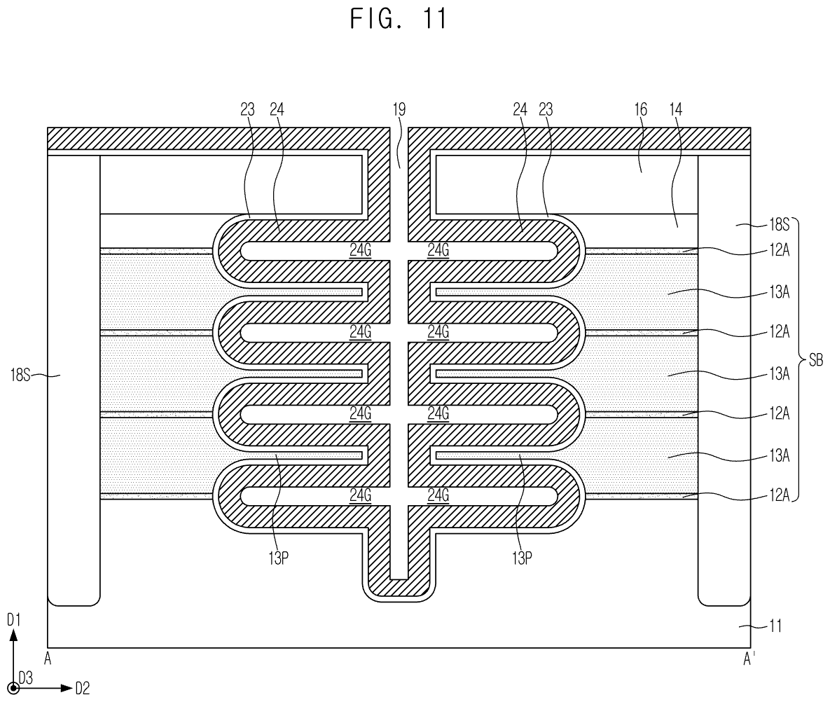

As illustrated in FIG. 11, a nano-sheet dielectric layer 23 may be formed on exposed portions of the narrow sheets 13P. The nano-sheet dielectric layer 23 may be referred to as a “gate dielectric layer”.

The nano-sheet dielectric layer 23 may be formed by oxidizing surfaces of the narrow sheets 13P. In an embodiment, the nano-sheet dielectric layer 23 may be formed by a deposition process of silicon oxide and a surface oxidation process of the narrow sheets 13P. The nano-sheet dielectric layer 23 may include silicon oxide, silicon nitride, metal oxide, metal oxide nitride, metal silicate, a high-k material, a ferroelectric material, an anti-ferroelectric material, or a combination thereof. The nano-sheet dielectric layer 23 may include SiO₂, Si₃N₄, HfO₂, Al₂O₃, ZrO₂, AlON, HfON, HfSiO, HfSiON, or a combination thereof. The nano-sheet dielectric layer 23 may be formed on all surfaces of the narrow sheets 13P.

A target layer 24 may be formed on the nano-sheet dielectric layer 23. The target layer 24 may be an initial material for forming a horizontal conductive line afterward. The target layer 24 may fully cover the narrow sheets 13P on the nano-sheet dielectric layer 23. The target layer 24 may extend in the third direction D3. The nano-sheet dielectric layer 23 and the target layer 24 may be conformally formed on sidewalls of the first linear opening 19. The target layer 24 may include a plurality of horizontal level unfilled spaces 24G. The horizontal level unfilled spaces 24G may be vertically disposed in the first direction D1. The horizontal level unfilled spaces 24G may horizontally extend in the third direction D3. The target layer 24 may include metal, a metal-based material, a semiconductive material, or a combination thereof. The target layer 24 may include molybdenum, molybdenum nitride, ruthenium, titanium nitride, tungsten, polysilicon, or a combination thereof. For example, the target layer 24 may include a TiN/W stack in which titanium nitride and tungsten are sequentially stacked. The target layer 24 may include an N-type work function material or a P-type work function material. The N-type work function material may have a low work function of 4.5 eV or lower, and the P-type work function material may have a high work function of 4.5 eV or higher.

From the perspective of a top view, the target layer 24 may surround a plurality of narrow sheets 13P in the third direction D3.

In an embodiment, the target layer 24 may include a seamless metal material, and the metal material may be self-aligned and deposited after the narrow sheets 13P are formed.

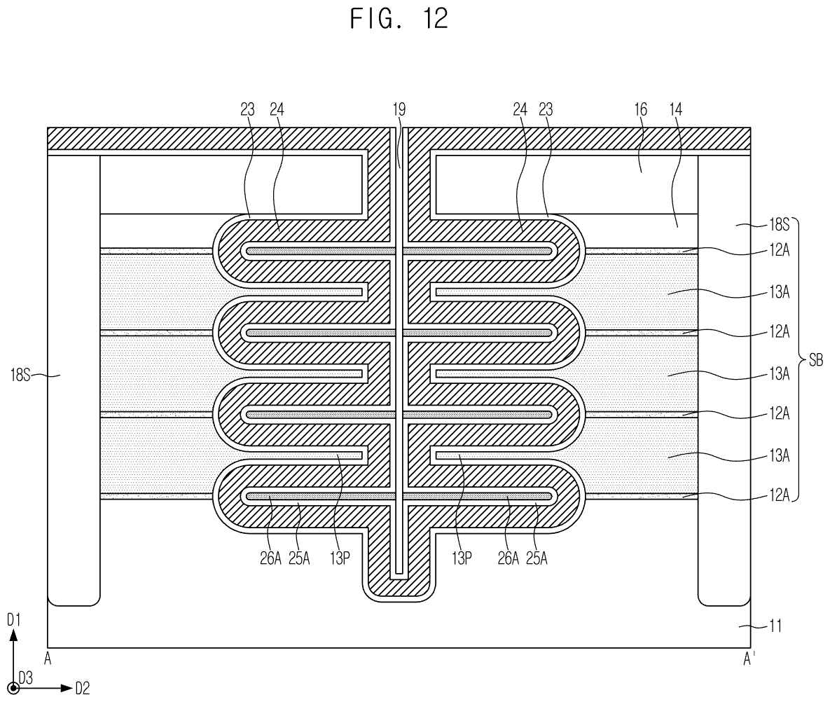

As illustrated in FIG. 12, a first liner layer 25A may be formed on the target layer 24, and inner barrier layers 26A may be formed on the first liner layer 25A. The inner barrier layers 26A may fill the remainder of the horizontal level unfilled space 24G on the first liner layer 25A. The first liner layer 25A and the inner barrier layers 26A may fill the horizontal level unfilled space 24G. The inner barrier layers 26A may be formed by deposition and etch processes of an etch barrier material. The first liner layer 25A may be a continuous layer extending in the first direction D1. The inner barrier layers 26A may be discontinuous layers that are vertically stacked in the first direction D1. The first liner layer 25A may include silicon oxide, and the inner barrier layers 26A may include polysilicon. When the inner barrier layers 26A include polysilicon, a subsequent annealing process may be performed to remove a seam within the polysilicon.

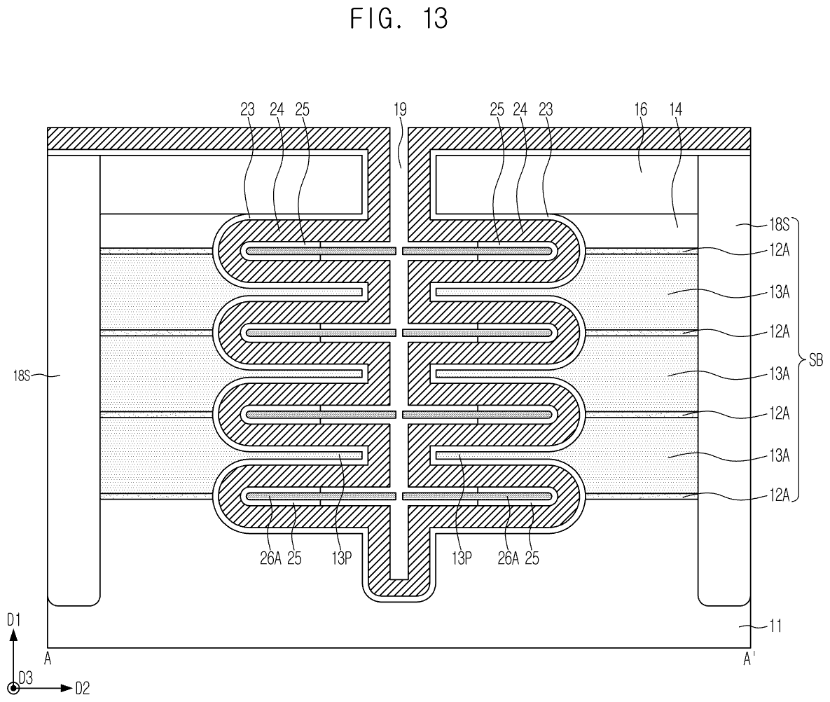

As illustrated in FIG. 13, the first liner layer 25A may be horizontally recessed to form a first liner 25. Portions of the inner barrier layers 26A may be exposed by the first liner 25.

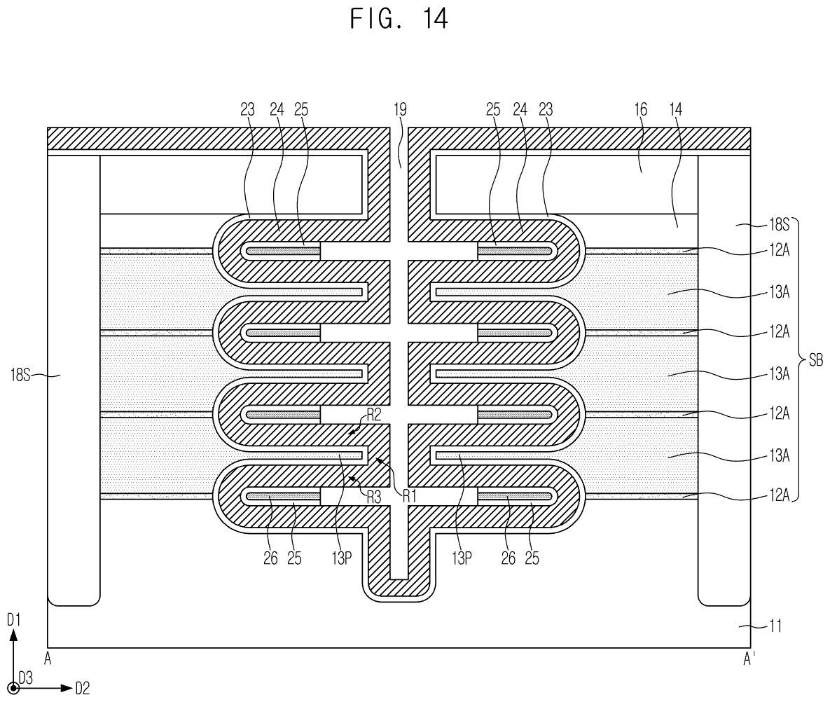

As illustrated in FIG. 14, the inner barrier layers 26A may be horizontally recessed to form an inner barrier 26. For example, when the inner barrier layers 26A include polysilicon, the polysilicon may be selectively cut.

A combination of the first liner 25 and the inner barrier 26 may be referred to as an “inner gap-fill portion” or an “inner gap-fill material”. After the recess processes for forming the first liner 25 and the inner barrier 26, portions R1, R2 and R3 of the target layer 24 may be exposed. The exposed portions R1, R2 and R3 of the target layer 24 may be referred to as “protrusions”.

As illustrated in FIG. 15, a first horizontal recess process may be performed on the target layer 24 to form a preliminary horizontal conductive line 27. The first horizontal recess process on the target layer 24 may be performed from the protrusions R1, R2 and R3. The first horizontal recess process on the target layer 24 may be performed using the inner gap-fill portion, i.e., the first liner 25 and the inner barrier 26, as etch barriers.

The preliminary horizontal conductive line 27 may include a plurality of cup-shaped portions 27A and a plurality of surrounding portions 27S. The cup-shaped portions 27A may be merged with the surrounding portions 27S. Parts of the cup-shaped portions 27A may be mutually merged to form the surrounding portions 27S. The narrow sheet 13P may be disposed between the plurality of cup-shaped portions 27A vertically stacked. The surrounding portions 27S may surround all surfaces of the narrow sheets 13P. Cross-sections of the cup-shaped portions 27A may each be like a “c” shape. Each of the cup-shaped portions 27A may cover an upper surface, a lower surface and one side surface of the first liner 25.

From the perspective of a top view, the preliminary horizontal conductive line 27 may surround the plurality of narrow sheets 13P in the third direction D3. Accordingly, the preliminary horizontal conductive lines 27 vertically stacked may be mutually merged.

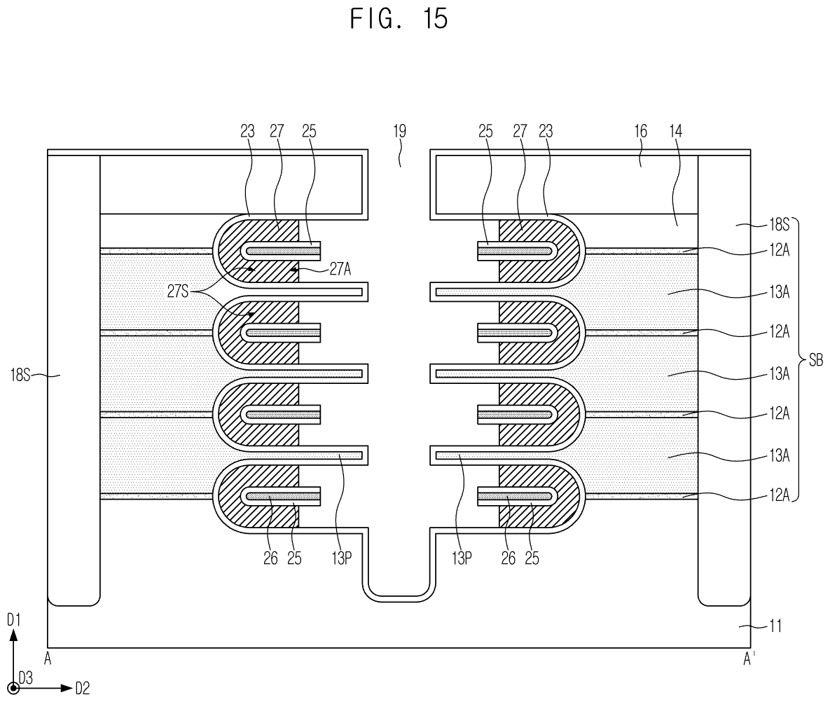

As illustrated in FIG. 16, a first spacer 28 may be formed on one side of the preliminary horizontal conductive line 27. After the first spacer 28 is formed, a capping-level space 28G may be defined. The capping-level space 28G may be disposed at each of upper and lower portions of the narrow sheets 13P. The capping-level space 28G may surround the narrow sheets 13P. The first spacer 28 may surround the narrow sheets 13P disposed at the same horizontal level in the third direction D3. The first spacer 28 may have a continuous structure in the first direction D1.

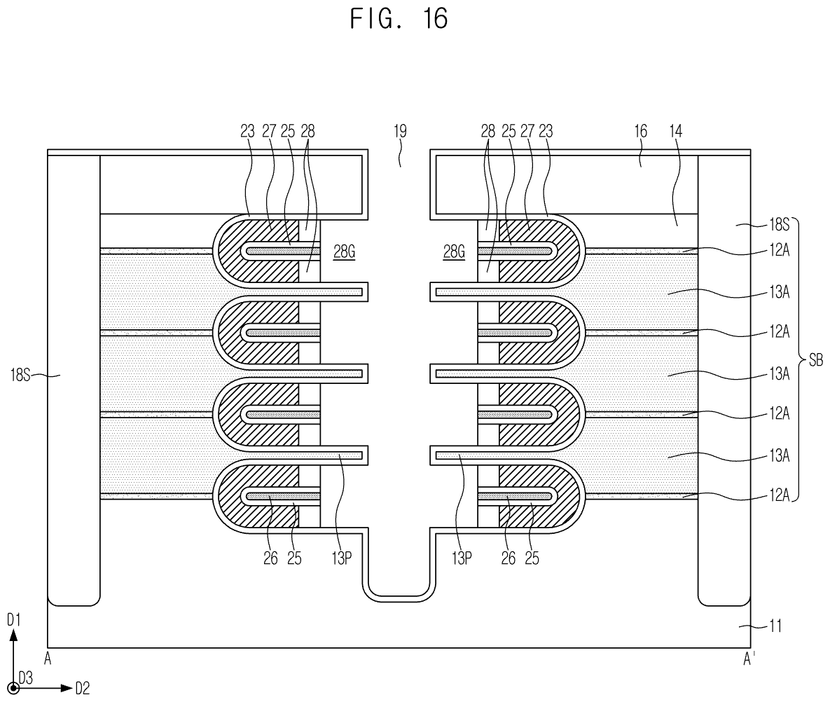

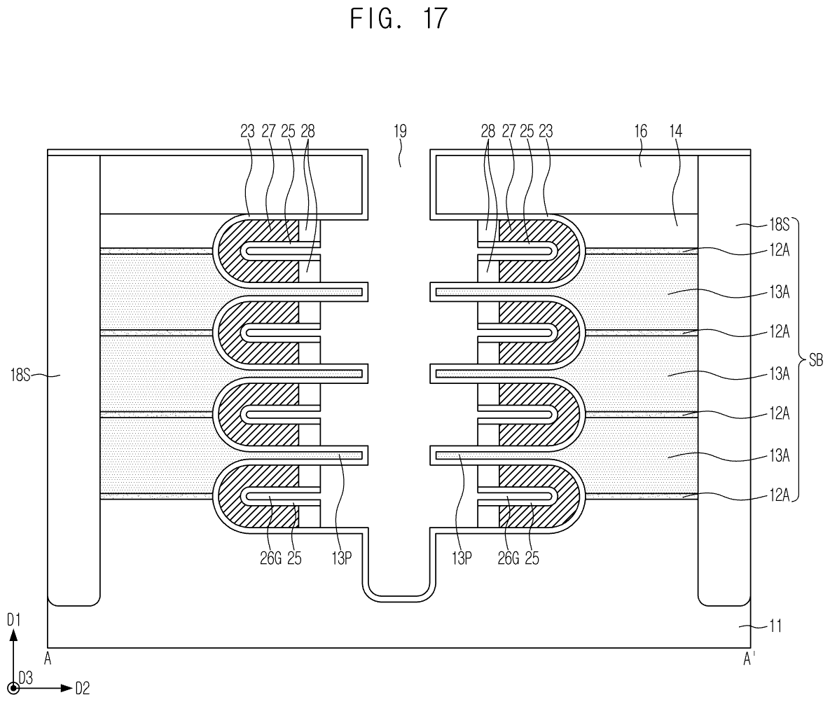

As illustrated in FIG. 17, the inner barrier 26 may be removed. A gap 26G may be formed in the space where the inner barrier 26 is removed.

As illustrated in FIG. 18, a second liner 29 may be formed on the first spacer 28 to fill the gap 26G. Then, after the forming of the second liner 29, a third liner 30 may be formed on the second liner 29. A stack of the second liner 29 and the third liner 30 may fill the capping-level space 28G. The third liner 30 may be disposed in the capping-level space 28G, and the second liner 29 may be conformally formed on the nano-sheet dielectric layer 23 and the capping space 28G. The second liner 29 may include an oxide-based material, and the third liner 30 may include a nitride-based material. The second liner 29 may include silicon oxide, and the third liner 30 may include silicon nitride.

A first lower protective structure may be formed to fill a bottom portion of the first linear opening 19 while the second and third liners 29 and 30 are formed. The first lower protective structure may include a stack of a dummy second liner 29T and a first bottom protective layer 30T. The first bottom protective layer 30T may include silicon oxide, and the dummy second liner 29T may include silicon nitride. The first bottom protective layer 30T and the third liner 30 may be the same material. The dummy second liner 29T and the second liner 29 may be the same material.

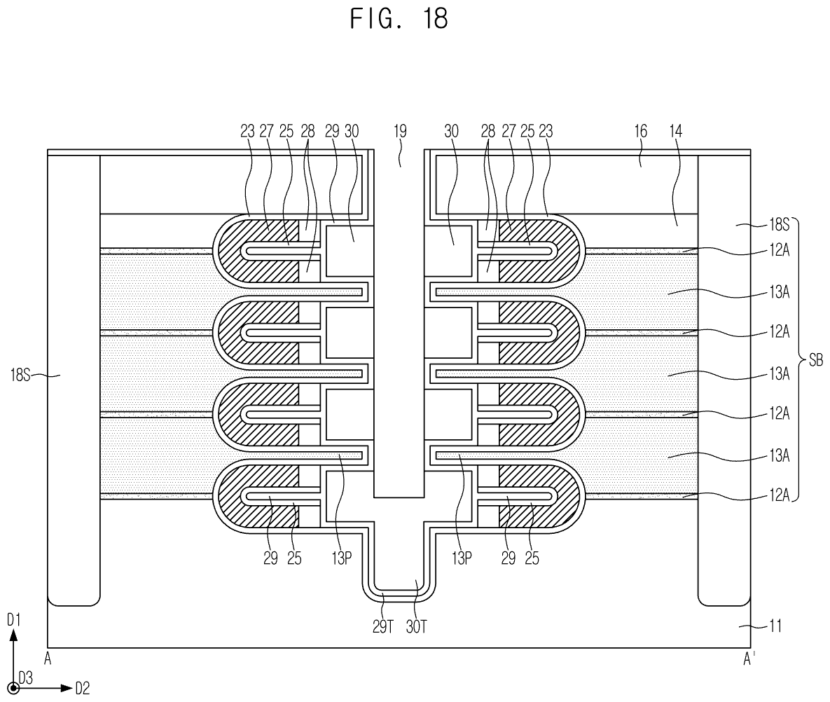

As illustrated in FIG. 19, a cutting process may be performed on the second liner 29. Accordingly, a portion of the third liner 30 may protrude.

A horizontal recess process may be performed on the narrow sheets 13P. Accordingly, sheet level recesses 31 may be formed.

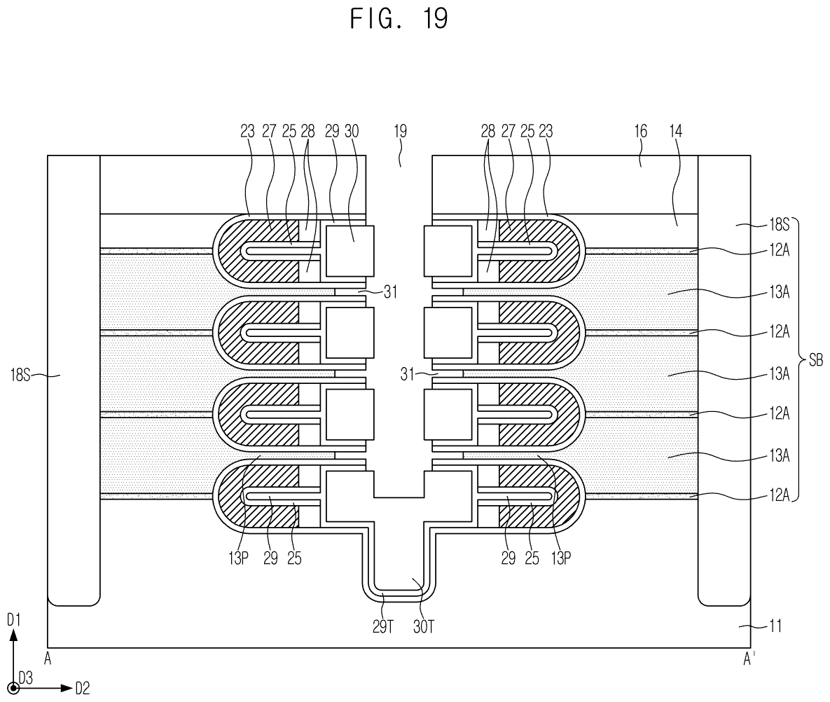

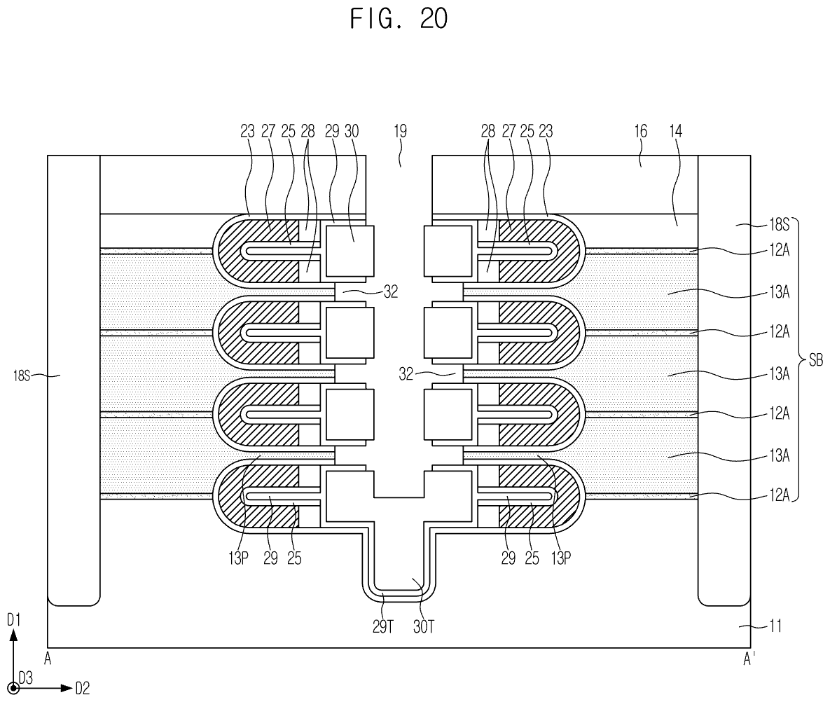

As illustrated in FIG. 20, a recess process may be performed on the nano-sheet dielectric layers 23. Accordingly, the sheet level recesses 31 may be expanded as indicated by reference numeral “32”. The sheet level recesses 32 may be disposed between the second liners 29.

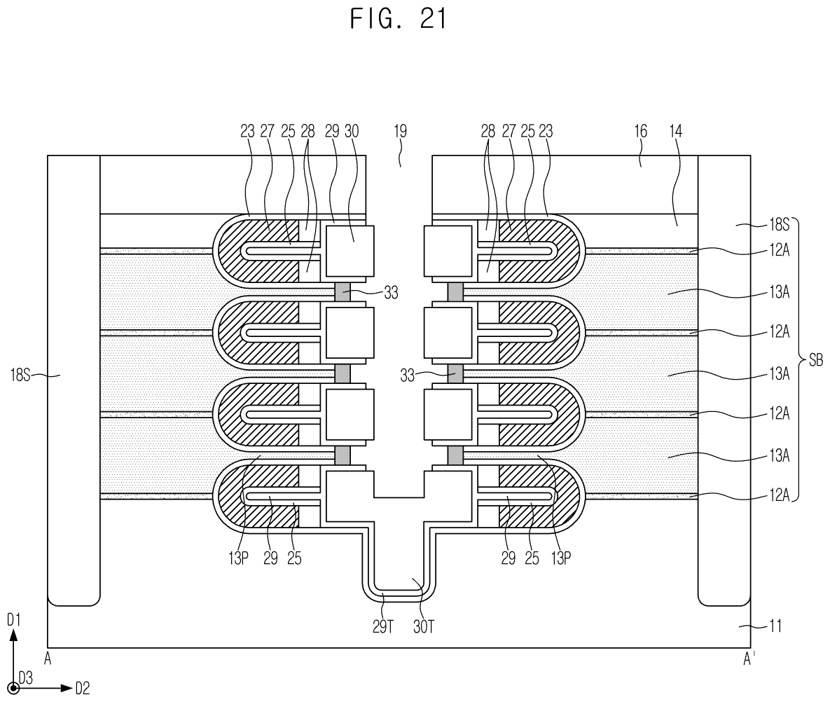

As illustrated in FIG. 21, first contact nodes 33 may be formed in the sheet level recesses 32. Forming the first contact nodes 33 may include depositing a conductive material filling the sheet level recesses 32 and performing an etch-back process on the conductive material. The first contact nodes 33 may include a semiconductive material. The first contact nodes 33 may include polysilicon, doped polysilicon, a silicon epitaxial layer, or a doped silicon epitaxial layer. The first contact nodes 33 may include doped polysilicon, and the doped polysilicon may include N-type dopants. Each of the first contact nodes 33 may be disposed between the second liners 29 that are vertically stacked. The first contact nodes 33 and the second liners 29 may not be self-aligned in the first direction D1. That is, each of the first contact nodes 33 may partially fill the undercut between the second liners 29 that are vertically stacked. The first contact nodes 33 may be inner contact nodes disposed in the sheet level recesses 32. In an embodiment, the first contact nodes 33 may be formed through selective epitaxial growth (SEG).

In an embodiment, a first doped region (refer to reference symbol “SR” in FIG. 4A) may be formed in one side of each of the narrow sheets 13P. A heat treatment process may be performed to form the first doped region, thereby allowing dopants to diffuse from each of the first contact nodes 33.

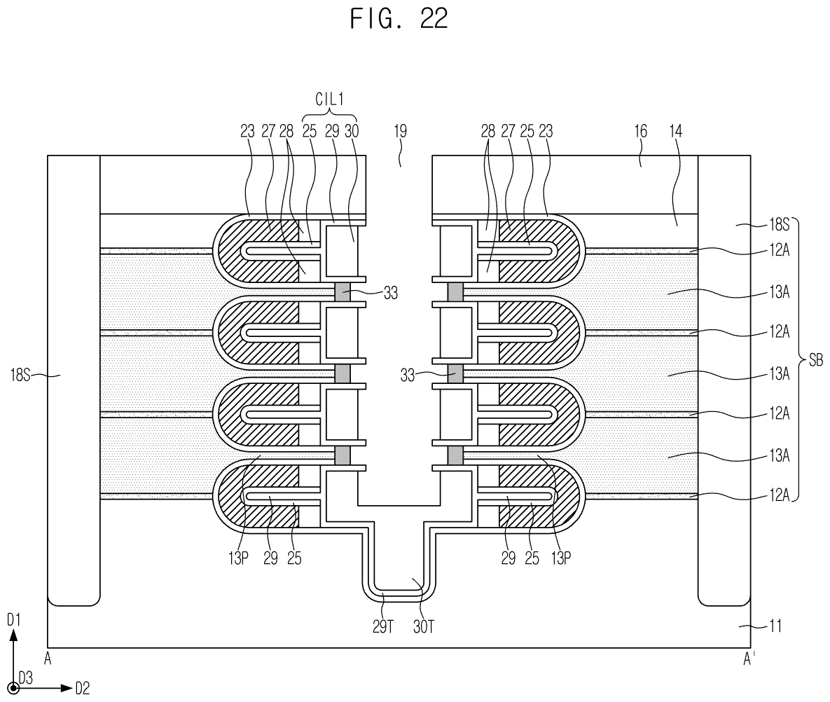

As illustrated in FIG. 22, the third liner 30 and the second protective layer 30T may be partially recessed.

A first inter-cell horizontal dielectric layer CIL1 may be formed by a series of processes as described above. The first inter-cell horizontal dielectric layer CIL1 may include the first liner 25, the second liner 29, and the third liner 30. The second liner 29 may fill an inner portion of the first liner 25, and the third liner 30 may fill an inner portion of the second liner 29. The first spacer 28 may be disposed between the preliminary horizontal conductive line 27 and the second liner 29. The preliminary horizontal conductive line 27 and the first spacer 28 may cover an outer surface of the first liner 25.

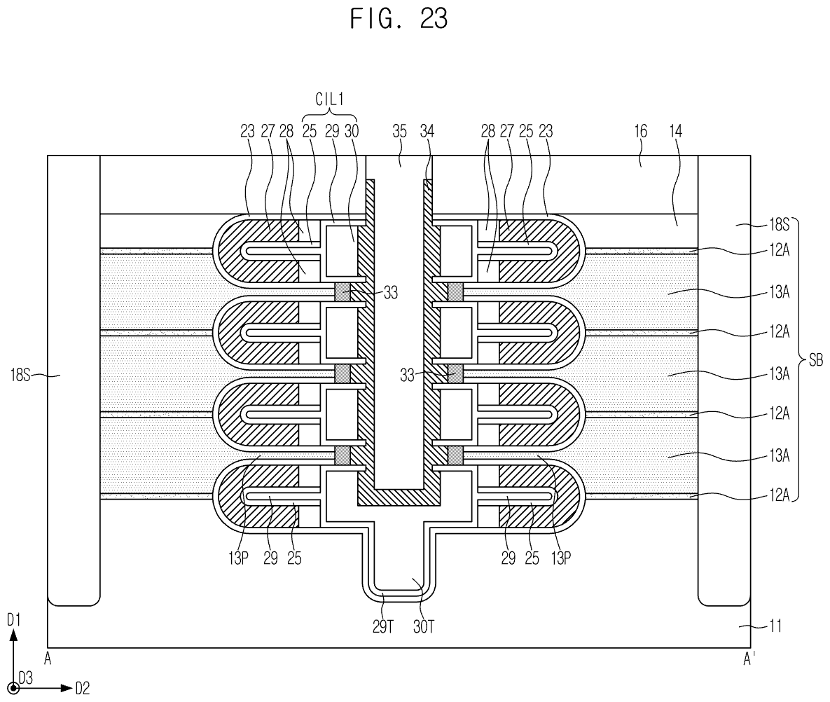

As illustrated in FIG. 23, a vertical conductive line 34 electrically coupled to the first contact nodes 33 may be formed. The vertical conductive line 34 may be conformally formed on the sidewalls and bottom surface of the first linear opening 19.

The vertical conductive line 34 may be coupled in common to the narrow sheets 13P disposed in the first direction D1. The vertical conductive line 34 may include a metal-based material. The vertical conductive line 34 may include titanium nitride, tungsten, or a combination thereof. To form the vertical conductive line 34, deposition and etch processes may be performed on a conductive line material.

The vertical conductive line 34 may extend vertically in the first direction D1. The vertical conductive line 34 may be coupled in common to the first contact nodes 33. Accordingly, the vertical conductive line 34 may be coupled in common to the narrow sheets 13P disposed in the first direction D1. In addition, the vertical conductive line 34 may be coupled in common to the narrow sheets 13P disposed adjacent to each other in the second direction D2. That is, the narrow sheets 13P disposed adjacent to each other in the second direction D2 may share a vertical conductive line 34.

A vertical isolation layer 35 may be formed to fill the first linear opening 19 on the vertical conductive line 34. The vertical isolation layer 35 may extend vertically in the first direction D1 and may also extend horizontally in the third direction D3. The vertical conductive lines 34 disposed adjacent to each other in the third direction D3 may be isolated by the vertical isolation layer 35. The vertical isolation layer 35 may include a dielectric material such as, for example, silicon oxide, silicon nitride, an air gap, or a combination thereof.

The vertical conductive line 34 may contact the second liner 29 and the third liner 30. A bottom surface of the vertical conductive line 34 may contact the second protective layer 30T.

The vertical conductive line 34 may correspond to the first conductive line BL described with reference to FIGS. 3 to 4B.

In an embodiment, an ohmic contact layer may be formed between the first contact node 33 and the vertical conductive line 34. The ohmic contact layer may be the same as the ohmic contact layer BLO described with reference to FIGS. 3 to 4B.

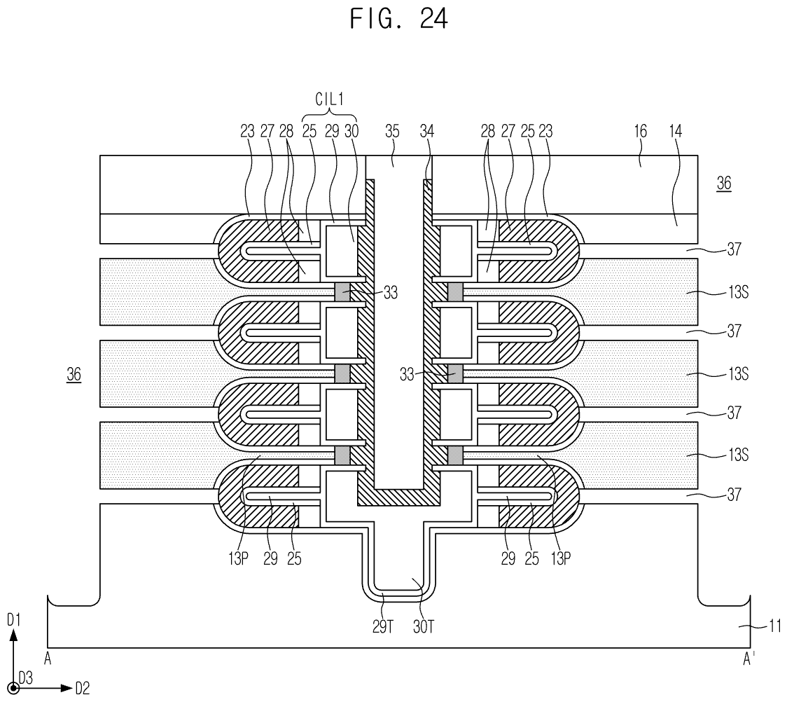

As illustrated in FIG. 24, the second linear sacrificial layer 18S may be removed to form a second linear opening 36.

After the second linear opening 36 is formed, the first mold layers 12A may be selectively stripped through the second linear opening 36. The first mold layers 12A may be removed using a wet or a dry etch process using a difference in the etch selectivity between the first mold layers 12A and the original body portions 13A. For example, in an embodiment, the first mold layers 12A include a silicon germanium layer, the original body portions 13A include a monocrystalline silicon layer, and the silicon germanium layer may be etched using an etchant or etch gas having a selectivity with respect to the monocrystalline silicon layer.

Sequentially, the original body portions 13A may be recessed using a wet or a dry etch process. The original body portions 13A may be thinned to form thinned body portions referred to hereinafter as “recessed body portions 13S”.

An inter-body recess 37 may be formed between the recessed body portions 13S that are vertically disposed.

Sequentially, the nano-sheet dielectric layer 23 may be cut through the inter-body recess 37 to expose a portion of the preliminary horizontal conductive line 27.

As illustrated in FIG. 25, a portion of the preliminary horizontal conductive line 27 may be cut to form a horizontal conductive line 38. A cut space of the preliminary horizontal conductive line 27 may be an extended capping space 39. The cutting process of the preliminary horizontal conductive line 27 may be referred to as a “second horizontal recess process”.

An uppermost horizontal conductive line 38 and a lowest horizontal conductive line 38 may be dummy lines 38U and 38L, respectively. The horizontal conductive line 38 may correspond to the second conductive line WL described with reference to FIGS. 3 to 4B.

In the embodiment described above, combining the first and second horizontal recess processes to form the horizontal conductive line 38 is advantageous because a length distribution of the horizontal conductive line 38 may be improved. Since a recess amount of the first horizontal recess process and a recess amount of the second horizontal recess process are small, the length of the horizontal conductive line 38 may be maintained uniformly. In addition, because the target layer 24 is formed seamlessly, excessive recessing due to a seam does not occur during the first and second horizontal recess processes. In addition, because the horizontal conductive line 38 is formed by the first and second horizontal recess processes of a seamless conductive material, resistance of the horizontal conductive line 38 may be improved.

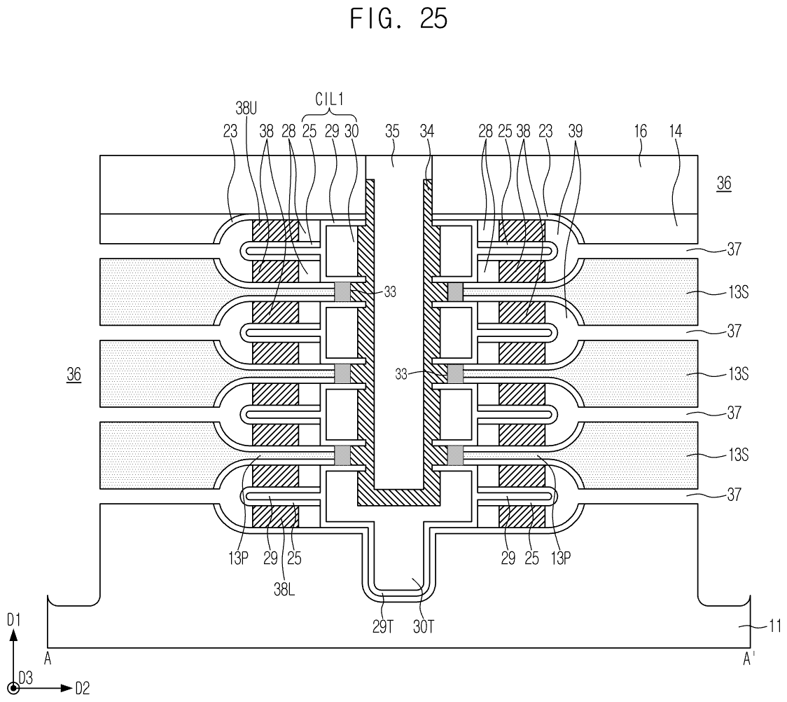

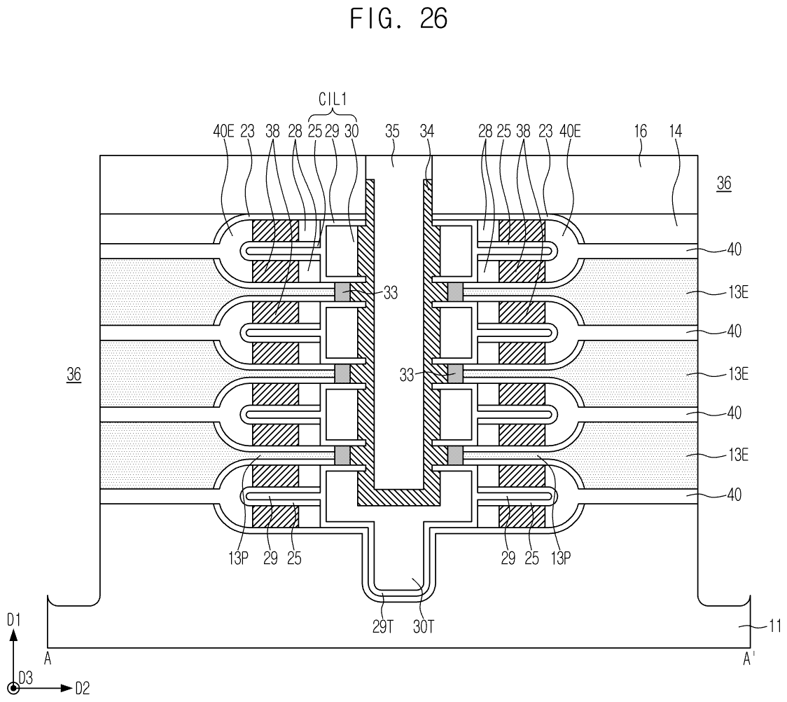

As illustrated in FIG. 26, second inter-cell horizontal dielectric layers 40 may be formed to fill the inter-body recesses 37. The second inter-cell horizontal dielectric layers 40 may include silicon oxide. Each of the second inter-cell horizontal dielectric layers 40 may include a second spacer 40E formed to fill the extended capping space 39. The nano-sheet dielectric layer 23 may cover a portion of the second spacer 40E. The second spacer 40E may surround the narrow sheets 13P at the same horizontal level in the third direction D3. The second spacer 40E may have a continuous structure in the first direction D1. The second inter-cell horizontal dielectric layers 40 and the second spacers 40E may have integral structures having the same material.

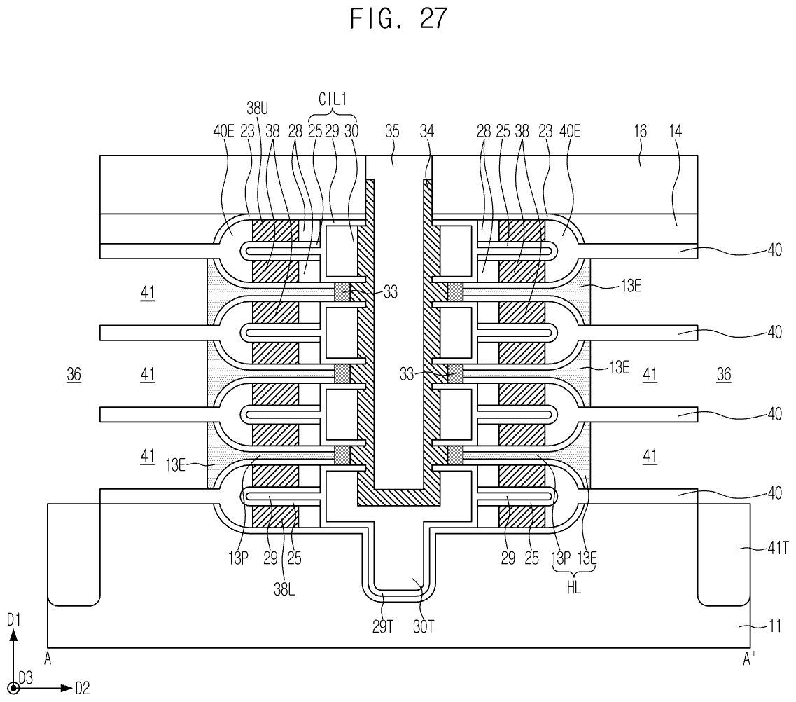

As illustrated in FIG. 27, following the formation of the second inter-cell horizontal dielectric layers 40, a second bottom protective layer 41T may be formed on a bottom portion of the second linear opening 36. The second bottom protective layer 41T may include a material having an etch selectivity with respect to the substrate 11. The second bottom protective layer 41T may include a dielectric material such as, for example, silicon oxide, silicon nitride, silicon carbon oxide, or a combination thereof.

Storage openings 41 may be formed by performing horizontal recessing of the recessed body portions 13S. The storage openings 41 may be referred to as “data storage element openings”. Nano-sheets HL may be formed by the recessing of the recessed body portions 13S. Each nano-sheet HL may include the narrow sheet 13P and a wide sheet 13E. The wide sheet 13E of the nano-sheet HL refers to the recessed body portion 13S remaining after the recessing. An average vertical height of the wide sheets 13E in the first direction D1 may be greater than an average vertical height of the narrow sheets 13P. The wide sheets 13E have a gradually increasing thickness in the second direction D2. Also, a horizontal length of each of the wide sheets 13E in the second direction D2 is less than a horizontal length of each of the narrow sheets 13P. The wide sheets 13E of the nano-sheets HL may each have a fan-like shape. The wide sheets 13E may be referred to as fan-shaped sheets, and the narrow sheets 13P may be referred to as flat plate-shaped sheets.

To form the nano-sheets HL each including the wide sheet 13E, the recessed body portions 13S may be etched isotropically, or anisotropically. One side of the wide sheet 13E, i.e., a side surface exposed by the storage opening 41, may have a flat shape. However, the embodiment is not limited in this way and the one side of the wide sheet 13E may have various shapes such as a rounded concave shape, a rounded convex shape, an angled concave shape, or an angled convex shape.

The second bottom protective layer 41T and a lowermost second inter-cell horizontal dielectric layer 40 may prevent loss of the substrate 11 during the recessing process of the recessed body portions 13S.

Each of the nano-sheets HL may include a first edge and a second edge. The first edge may refer to a portion coupled to the vertical conductive line 34 and the first contact node 33. The second edge may refer to a portion exposed by each of the storage openings 41. Each of the storage openings 41 may be disposed between a pair of corresponding adjacent second inter-cell horizontal dielectric layers 40.

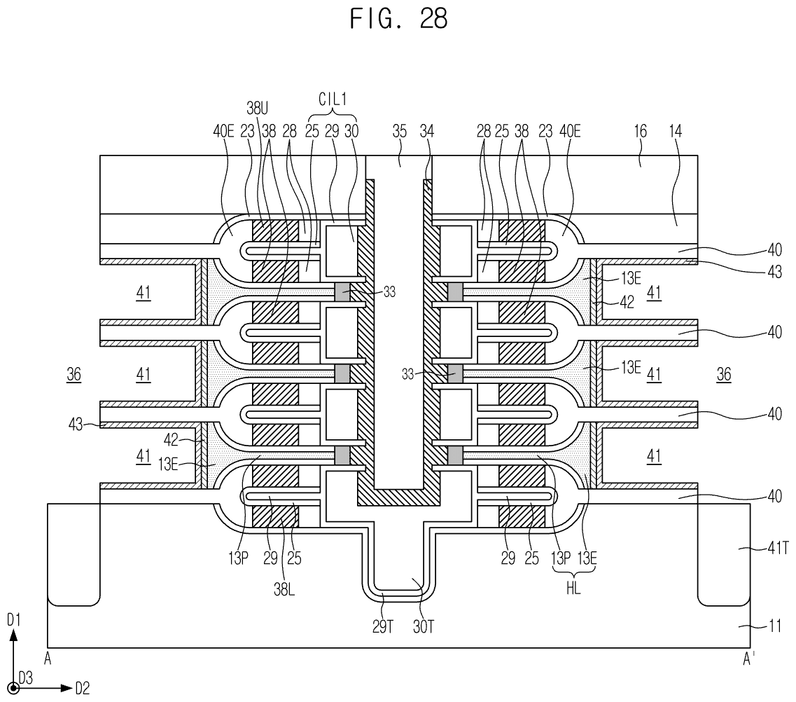

As illustrated in FIG. 28, a pre-cleaning process may be performed on one side of each of the nano-sheets HL, i.e., the surfaces of the wide sheets 13E.

A second contact node 42 may be formed on each of the wide sheets 13E of the nano-sheets HL. Forming the second contact nodes 42 may include conformally depositing a conductive material on each of the storage openings 41 and performing an etch-back process on the conductive material. The second contact nodes 42 may include a semiconductive material. The second contact nodes 42 may include doped polysilicon, and the doped polysilicon may include N-type dopants. Each of the second contact nodes 42 may be disposed between a corresponding pair of adjacent second inter-cell horizontal dielectric layers 40 that are vertically stacked.

In an embodiment, forming the second contact nodes 42 may include selective epitaxial growth (SEG). For example, a semiconductor material may be grown from a side surface of the wide sheet 13E through the selective epitaxial growth (SEG). The second contact nodes 42 may include SEG Si. Because the wide sheet 13E includes monocrystalline silicon, a silicon layer may be epitaxially grown along a crystal surface of the side surface of the wide sheet 13E. The second contact nodes 42 may include a dopant. When the silicon layer is grown using the selective epitaxial growth (SEG), dopants may be doped in situ. Therefore, the second contact nodes 42 may be a doped epitaxial layer. The second contact nodes 42 may include an N-type dopant as a dopant. The N-type dopant may include phosphorus, arsenic, antimony, or a combination thereof. The second contact nodes 42 may include a phosphorus-doped silicon epitaxial layer, i.e., doped SEG SiP, formed by the selective epitaxial growth (SEG). In an embodiment, the first contact nodes 33 may also be formed by the selective epitaxial growth (SEG).

One side of the second contact node 42 may have various shapes. For example, one side of the second contact node 42 may have a rounded concave shape, a rounded convex shape, an angled concave shape, or an angled convex shape.

A second doped region (refer to reference symbol “DR” in FIG. 4A) may be formed in each of the wide sheets 13E of the nano-sheets HL. A heat treatment process may be performed to form the second doped region, and thus dopants may diffuse from the second contact node 42. In another method for forming the second doped region, a gas phase doping method may be applied. As described with reference to FIG. 4A, each of the nano-sheets HL may include the first doped region DR, the second doped region SR, and the channel CH. In an embodiment, an ohmic contact layer including metal silicide may be further formed after the second contact nodes 42 are formed.

First electrodes 43 of a data storage element may be formed on the second contact nodes 42. The first electrodes 43 may each have a horizontally-oriented cylindrical shape. Each of the first electrodes 43 may be disposed in a different one of the storage openings 41. The first electrodes 43 disposed adjacent to each other in the second direction D2 may be spaced apart from each other by the second linear opening 36. The first electrodes 43 disposed adjacent to each other in the first direction D1 may be spaced apart from each other by the second inter-cell horizontal dielectric layer 40. Forming the first electrodes 43 may include depositing a metal material, gap-filling a sacrificial material, and isolating the metal material in a vertical/horizontal direction. The sacrificial material may include oxide or polysilicon.

Each of the first electrodes 43 may include an inner space and a plurality of outer surfaces, and the inner space of the first electrode 43 may include a plurality of inner surfaces. The outer surfaces of the first electrode 43 may include a vertical outer surface and a plurality of horizontal outer surfaces. The vertical outer surface of the first electrode 43 may extend vertically in the first direction D1, and the horizontal outer surfaces of the first electrode 43 may horizontally extend in the second direction D2 or the third direction D3. The inner space of the first electrode 43 may be a three-dimensional space.

Among the outer surfaces of the first electrode 43, the vertical outer surface may be electrically coupled to the nano-sheet HL and the second contact node 42.

The first electrode 43 may include metal, noble metal, metal nitride, conductive metal oxide, conductive noble metal oxide, metal carbide, metal silicide, or a combination thereof. For example, the first electrode 43 may include titanium (Ti), titanium nitride (TIN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, or a titanium silicon nitride/titanium nitride (TiSiN/TIN) stack, or a combination thereof.

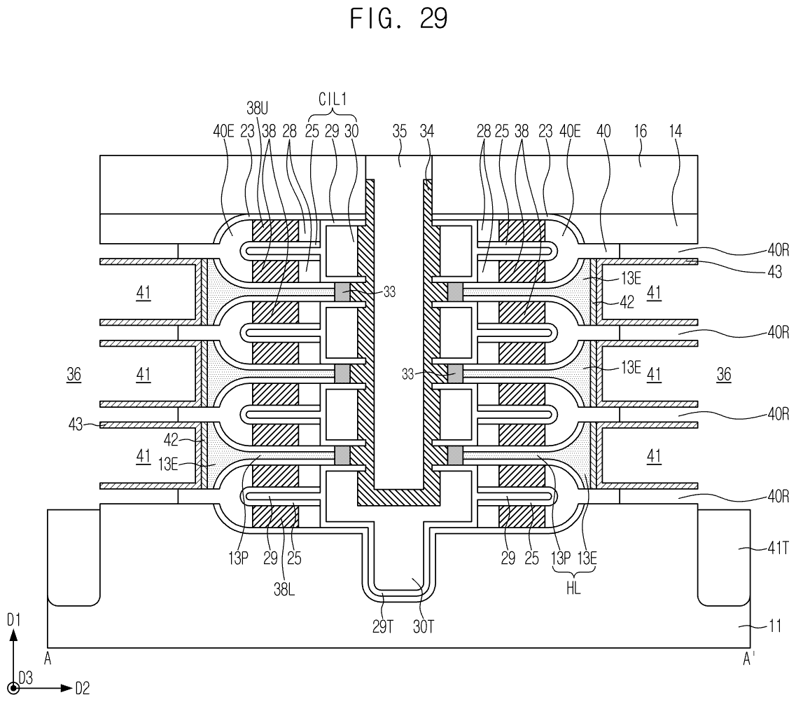

As illustrated in FIG. 29, a cleaning process may be performed to horizontally recess a portion of the second inter-cell horizontal dielectric layers 40 (refer to reference numeral “40R”). Accordingly, outer walls of the first electrode 43 may be partially exposed. The first electrode 43 may have a semi-cylindrical shape. A horizontal recess depth of the second inter-cell horizontal dielectric layer 40 may be a depth that does not expose the second contact node 42. When the second inter-cell horizontal dielectric layers 40 include silicon oxide, the cleaning process may include an oxide cleaning process.

As described above, a portion of the second inter-cell horizontal dielectric layer 40 may be horizontally recessed, thereby securing an outer diameter of the first electrode 43.

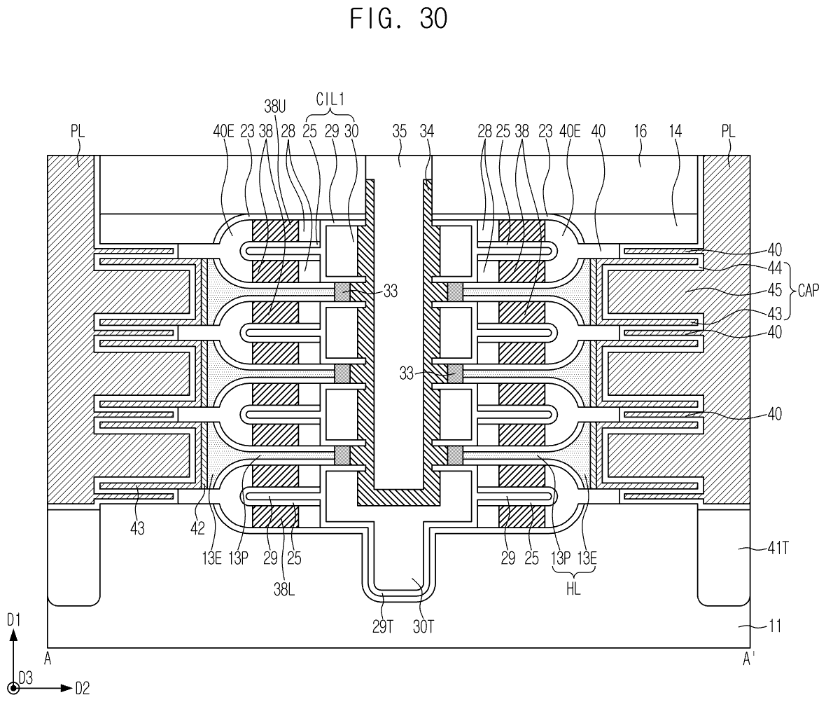

As illustrated in FIG. 30, a dielectric layer 44 and a second electrode 45 may be sequentially formed on the first electrodes 43. The first electrode 43, the dielectric layer 44 and the second electrode 45 may be a data storage element CAP. The second electrodes 45 of the data storage elements CAP may be merged with each other to become a common plate PL.

The dielectric layer 44 may conformally cover the inner surfaces of the first electrode 43. The second electrode 45 may be disposed on the inner spaces of the first electrode 43 on the dielectric layer 44.

The first electrode 43 may have a semi-cylindrical shape. The semi-cylindrical shape of the first electrode 43 may include cylindrical inner surfaces and semi-cylindrical outer surfaces. The dielectric layer 44 and the second electrode 45 may be disposed on the cylindrical inner surfaces of the first electrode 43. A portion of the dielectric layer 44 and a portion of the second electrode 45 may extend to be disposed on the semi-cylindrical outer surfaces of the first electrode 43. The second electrode 45 may extend vertically in the first direction D1.

The dielectric layer 44 may be referred to as a “capacitor dielectric layer” or a “memory layer”. The dielectric layer 44 may include silicon oxide, silicon nitride, a high-k material, a ferroelectric material, an antiferroelectric material, a perovskite material, or a combination thereof. The dielectric layer 44 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). The dielectric layer 44 may include a ZA (ZrO₂/Al₂O₃) a ZAZ stack, (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, a HZHZ (HfO₂/ZrO₂/HfO₂/ZrO₂) stack, or AHZAZHA (Al₂O₃/HfO₂/ZrO₂/Al₂O₃/ZrO₂/HfO₂/Al₂O₃) stack.

The second electrode 45 may include metal, noble metal, metal nitride, conductive metal oxide, conductive noble metal oxide, metal carbide, metal silicide, or a combination thereof. For example, the second electrode 45 may include titanium (Ti), titanium nitride (TIN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, a titanium silicon nitride/titanium nitride/tungsten (TiSiN/TIN/W) stack, or a combination thereof. The second electrode 45 may also include a combination of a metal-based material and a silicon-based material. For example, titanium nitride, tungsten and polysilicon may be sequentially stacked in the second electrode 45.

In an embodiment, an interface control layer (NOT SHOWN) may be further formed between the first electrode 43 and the dielectric layer 44 to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 45 and the dielectric layer 44.

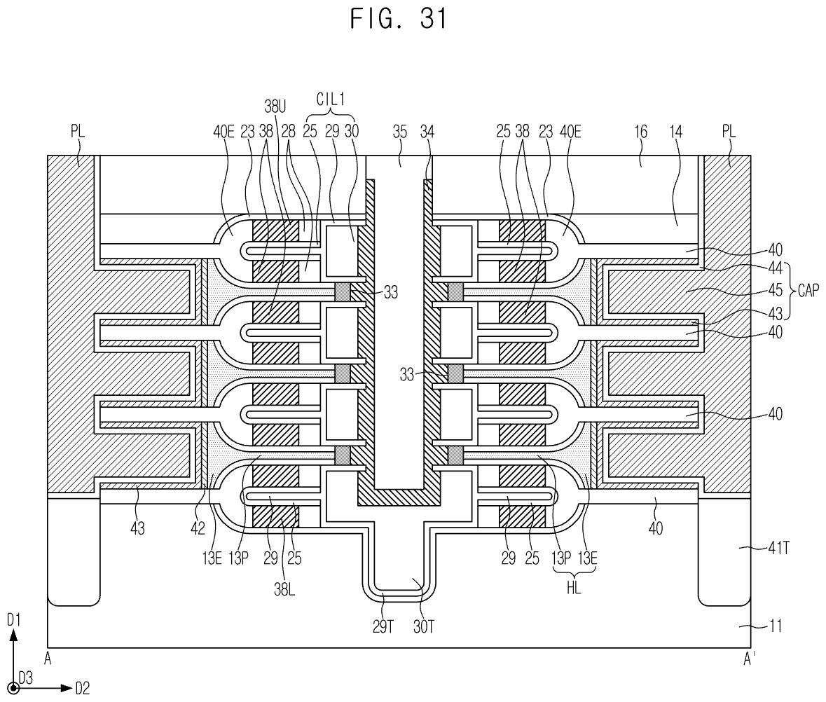

FIG. 31 illustrates a view of a semiconductor device formed utilizing a method for fabricating the semiconductor device in accordance with an embodiment of the present disclosure.

A series of processes described with reference to FIGS. 5 to 28 may be performed.

After the first electrodes 43 are formed, the horizontal recess process of the second inter-cell horizontal dielectric layers 40 described with reference to FIG. 29 may be omitted.

As illustrated in FIG. 31, a dielectric layer 44 and a second electrode 45 may be sequentially formed on the first electrodes 43. The first electrode 43, the dielectric layer 44 and the second electrode 45 may form a data storage element CAP.

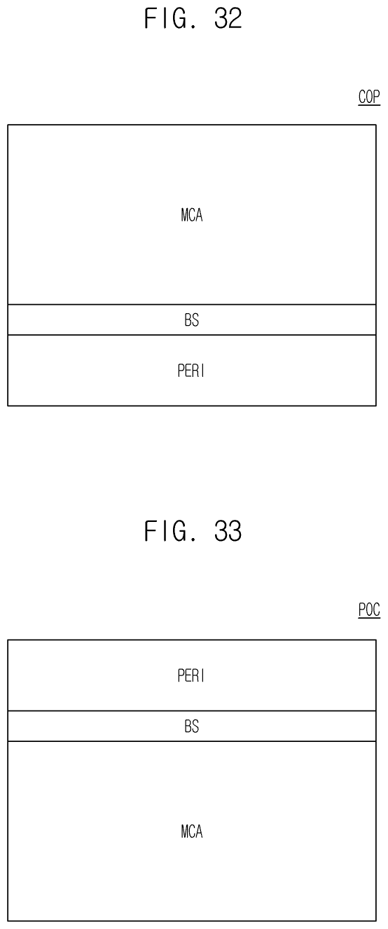

FIGS. 32 and 33 are schematic cross-sectional views of a semiconductor device in accordance with embodiments of the present disclosure.

As illustrated in FIG. 32, a semiconductor device COP may include a memory cell array MCA, a peripheral circuit portion PERI, and a bonding interface BS disposed between the memory cell array MCA and the peripheral circuit portion PERI. In the semiconductor device COP, the memory cell array MCA may be disposed at a higher level than the peripheral circuit portion PERI. The semiconductor device COP may be referred to as a “Peri Under Cell array (PUC) structure”. The memory cell array MCA may include a substrate on which back grinding is performed and an array of memory cells formed over the substrate. For example, as described with reference to FIG. 30, after the data storage element CAP is formed, the substrate 11 may be flipped over through a wafer flip, and then the substrate 11 may be partially ground back.

As illustrated in FIG. 33, a semiconductor device POC may include a memory cell array MCA, a peripheral circuit portion PERI, and a bonding interface BS disposed between the memory cell array MCA and the peripheral circuit portion PERI. In the semiconductor device POC, the memory cell array MCA may be disposed at a lower level than the peripheral circuit portion PERI. The semiconductor device POC may be referred to as a “Cell array Under Peri (CUP) structure”. Forming the peripheral circuit portion PERI may include forming a plurality of control circuits on a peripheral circuit substrate and forming multi-level interconnection on the control circuits.

In FIG. 32 and FIG. 33, the bonding interface BS may include pad bonding, hybrid bonding, oxide-to-oxide bonding, metal-to-metal bonding, or a combination thereof. The hybrid bonding may refer to a combination of the pad bonding and the oxide-to-oxide bonding. The pad bonding may include forming a cell bonding pad for a memory cell array, forming a peripheral circuit bonding pad for a peripheral circuit portion, performing a wafer flip so that the cell bonding pad and the peripheral circuit bonding pad face each other, and performing wafer bonding.

The semiconductor device COP illustrated in FIG. 32 may perform the wafer flip on the substrate on which the memory cell array is formed so that the cell bonding pad and the peripheral circuit bonding pad face each other, after the cell bonding pad and the peripheral circuit bonding pad are formed. The semiconductor device POC illustrated in FIG. 33 may perform the wafer flip on the substrate on which the peripheral circuit portion is formed so that the cell bonding pad and the peripheral circuit bonding pad face each other, after the cell bonding pad and the peripheral circuit bonding pad are formed.

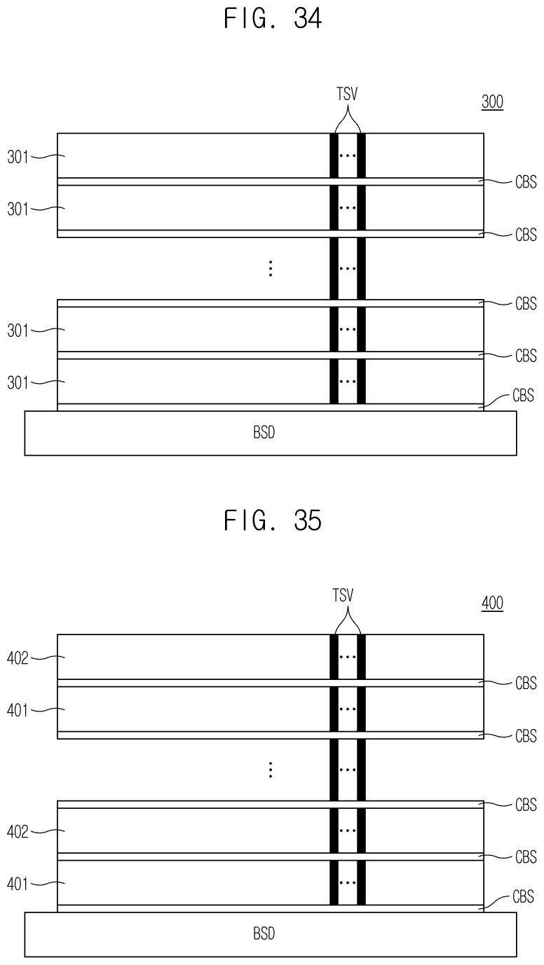

FIGS. 34 and 35 illustrate various views illustrating a stack assembly in accordance with an embodiment of the present disclosure.

As illustrated in FIG. 34, a stack assembly 300 may include an assembly of semiconductor dies. For example, the stack assembly 300 may include a first semiconductor die BSD and a plurality of second semiconductor dies 301. The first semiconductor die BSD may include logic circuits. Each of the second semiconductor dies 301 may include memory cell arrays according to embodiments described above. Each of the second semiconductor dies 301 may include structures in which a memory cell array and a peripheral circuit portion are stacked, for example, the semiconductor device COP illustrated in FIG. 32 or the semiconductor device POC illustrated in FIG. 33. The logic circuits of the first semiconductor die BSD may be different from the peripheral circuit portions of the second semiconductor dies 301. The second semiconductor dies 301 may have chip levels or wafer levels.

The second semiconductor dies 301 may be electrically coupled to each other through a plurality of through silicon vias TSV and bonding interfaces CBS. The first semiconductor die BSD and a lowermost second semiconductor die 301 may be electrically coupled to each other through the bonding interface CBS. The second semiconductor dies 301 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

In an embodiment, the second semiconductor dies 301 may be wafer-flipped and ground back to form the bonding interfaces CBS.

As illustrated in FIG. 35, a stack assembly 400 may include an assembly of semiconductor dies. For example, the stack assembly 400 may include a first semiconductor die BSD, a plurality of second semiconductor dies 401, and a plurality of third semiconductor dies 402. The first semiconductor die BSD may include logic circuits. Each of the second semiconductor dies 401 and each of the third semiconductor dies 402 may include memory cell arrays according to embodiments described above. The second semiconductor dies 401 and the third semiconductor dies 402 may have different structures.

Each of the second semiconductor dies 401 may include the semiconductor device COP illustrated in FIG. 32 in which a memory cell array is stacked over a peripheral circuit portion. Each of the third semiconductor dies 402 may include the semiconductor device POC illustrated in FIG. 33 in which a peripheral circuit portion is stacked over a memory cell array.

In an embodiment, each of the second semiconductor dies 401 may include the semiconductor device POC illustrated in FIG. 33 in which a peripheral circuit portion is stacked over a memory cell array, and each of the third semiconductor dies 402 may include the semiconductor device COP illustrated in FIG. 32 in which a memory cell array is stacked over a peripheral circuit portion.

The logic circuits of the first semiconductor die BSD may be different from the peripheral circuit portions of the second and third semiconductor dies 401 and 402. The second and third semiconductor dies 401 and 402 may have chip levels or wafer levels.

The second and third semiconductor dies 401 and 402 may be electrically coupled to each other through a plurality of through silicon vias TSV and bonding interfaces CBS. The first semiconductor die BSD and a lowermost second semiconductor die 401 may be electrically coupled to each other through the bonding interface CBS. The second and third semiconductor dies 401 and 402 may be referred to as “core dies”, “semiconductor chips”, or “memory chips”.

The bonding interface CBS may include micro-bump, pad bonding, hybrid bonding, oxide-to-oxide bonding, metal-to-metal bonding, or a combination thereof.

In an embodiment, wafer-flip and back grinding may be performed to form the bonding interface CBS. For example, the second semiconductor dies 401 and/or the third semiconductor dies 402 may be wafer-flipped and ground back.

The stack assemblies 300 and 400 illustrated in FIGS. 34 and 35 may be high bandwidth memories.

According to various embodiments of the present disclosure, it is possible to improve length distribution of a horizontal conductive line because the horizontal conductive line is formed by a recess process of a seamless conductive material.

According to various embodiments of the present disclosure, a seamless horizontal conductive line may be formed, which makes it possible to improve resistance of the horizontal conductive line.

While the embodiments of the present disclosure have been illustrated and described with respect to specific embodiments and drawings, the disclosed embodiments are not intended to be restrictive. Further, it is noted that the embodiments of the present disclosure may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A method for fabricating a semiconductor device, the method comprising:
forming a mold stack including a plurality of preliminary nano-sheets over a substrate;
forming a target layer surrounding portions of the preliminary nano-sheets;
performing a first horizontal recess process on the target layer and forming a preliminary horizontal conductive line; and
performing a second horizontal recess process on the preliminary horizontal conductive line and forming a horizontal conductive line.

2. The method of claim 1, wherein forming the target layer includes forming a metal-based material surrounding all surfaces of the preliminary nano-sheets.

3. The method of claim 1, wherein forming the target layer includes forming a nano-sheet dielectric layer surrounding all surfaces of the preliminary nano-sheets.

4. The method of claim 1, wherein performing the first horizontal recess process includes:
forming inner gap-fill materials on the target layer;
exposing a portion of the target layer by selectively cutting the inner gap-fill materials; and
etching an exposed portion of the target layer.

5. The method of claim 4, wherein the inner gap-fill materials include oxide, nitride, or a combination thereof.

6. The method of claim 1, wherein performing the second horizontal recess process includes:
forming a linear opening in the mold stack;
removing a portion of the mold stack from the linear opening and forming inter-body recesses; and
etching a portion of the preliminary horizontal conductive line through the inter-body recesses.

7. The method of claim 1, wherein in the mold stack, epitaxially-grown first semiconductor layers are alternately stacked with epitaxially-grown second semiconductor layers.

8. The method of claim 1, wherein in the mold stack, epitaxially-grown silicon layers are alternately stacked with epitaxially-grown silicon germanium layers.

9. The method of claim 1, further comprising:
after forming the horizontal conductive line,
selectively trimming one side of the preliminary nano-sheets to form narrow sheets;
forming a vertical conductive line coupled to the narrow sheets;
selectively recessing the other side of the preliminary nano-sheets to form wide sheets horizontally extending from the narrow sheets; and
forming data storage elements each electrically coupled to the wide sheets, respectively.

10. The method of claim 9, further comprising forming first contact nodes on the narrow sheets, before forming the vertical conductive line.

11. The method of claim 9, further comprising forming second contact nodes on the wide sheets, before forming the data storage elements.

12. A method for fabricating a semiconductor device, the method comprising:
forming a mold stack including nano-sheet target layers that are vertically stacked over a substrate;
trimming first portions of the nano-sheet target layers to form narrow sheets;
forming a target layer surrounding each of the narrow sheets;
performing a first horizontal recess process on the target layer to form a preliminary horizontal conductive line;
forming a vertical conductive line coupled in common to the narrow sheets;
horizontally recessing second portions of the nano-sheet target layers to form wide sheets;
performing a second horizontal recess process on the preliminary horizontal conductive line to form a horizontal conductive line surrounding each of the narrow sheets; and
forming data storage elements coupled to the wide sheets, respectively.

13. The method of claim 12, wherein forming the target layer includes forming a metal-based material surrounding all surfaces of the narrow sheets.

14. The method of claim 12, further comprising forming a nano-sheet dielectric layer surrounding all surfaces of the narrow sheets, before the forming of the target layer.

15. The method of claim 12, wherein performing the first horizontal recess process includes:
forming inner gap-fill materials on the target layer;
exposing a portion of the target layer by selectively cutting the inner gap-fill materials; and
etching an exposed portion of the target layer.

16. The method of claim 12, wherein performing the second horizontal recess process includes:
forming a linear opening in the mold stack;
removing a portion of the mold stack from the linear opening and forming inter-body recesses between the nano-sheet target layers; and
etching a portion of the preliminary horizontal conductive line through the inter-body recesses.

17. A semiconductor device comprising:
a plurality of nano-sheets that are vertically disposed;
a first conductive line coupled in common to first edges of the nano-sheets;
data storage elements coupled to second edges of the nano-sheets, respectively;
second conductive lines surrounding the nano-sheets, respectively;
first inter-cell horizontal dielectric layers disposed between the second conductive lines; and
second inter-cell horizontal dielectric layers disposed between the data storage elements and horizontally extending to contact the horizontal conductive lines.

18. The semiconductor device of claim 17, further comprising:
a first spacer disposed between the second conductive lines and the first inter-cell horizontal dielectric layers; and
a second spacer horizontally extending from each of the second inter-cell horizontal dielectric layers and contacting the second conductive lines.

19. The semiconductor device of claim 18, wherein the second inter-cell horizontal dielectric layers and the second spacer have an integral structure.

20. The semiconductor device of claim 18, wherein the second spacer covers one side of each of the first inter-cell horizontal dielectric layers.

21. The semiconductor device of claim 17, wherein the first and second inter-cell horizontal dielectric layers each include silicon oxide, silicon carbon oxide, silicon nitride, or a combination thereof.

22. The semiconductor device of claim 17, wherein each of the first inter-cell horizontal dielectric layers includes:
a first liner contacting each of the second conductive lines;
a second liner contacting each of the first conductive line; and
a third liner disposed between the second liner and the first conductive line,
wherein the third liner partially fills an inner portion of the second liner, and a portion of the second liner fills an inner portion of the first liner.

23. The semiconductor device of claim 17, wherein each of the nano-sheets includes:
a narrow sheet coupled to the first conductive line; and
a wide sheet coupled to each of the data storage elements and having a thickness that gradually increases from the narrow sheet toward the data storage element.

24. The semiconductor device of claim 17, further comprising:
a first contact node disposed between the vertical conductive line and the nano-sheets; and
a second contact node disposed between the data storage elements and the nano-sheets.
